(19) United States
(12) Patent Application Publication
(10) Pub. No.: US 2026/0143576 A1
(43) Pub. Date: May 21, 2026

(54) EXTREME ULTRAVIOLET LIGHT GENERATION SYSTEM AND ELECTRONIC DEVICE MANUFACTURING METHOD

(71) Applicant: Gigaphoton Inc., Oyama-shi (JP)

(72) Inventor: Shogo KITASAKA, Oyama-shi (JP)

(73) Assignee: Gigaphoton Inc., Oyama-shi (JP)

(21) Appl. No.: 19/353,140

(22) Filed: Oct. 8, 2025

(30) Foreign Application Priority Data
Nov. 19, 2024 (JP) 2024-201566

(51) Int. Cl. H05G 2/00; G01N 21/956; G03F 1/22; G03F 7/00

(52) U.S. Cl. CPC H05G 2/0084; G01N 21/956; G03F 1/22; G03F 7/70033; H05G 2/0023; H05G 2/0027; G01N 2021/95676; G01N 2201/06113

(57) ABSTRACT

An extreme ultraviolet light generation system generating extreme ultraviolet light by irradiating targets with pulse laser light includes a chamber; a target supply unit configured to continuously generate the targets at a specific time interval and supply the targets into the chamber; a timing sensor configured to detect the target passing through a first region and output a signal; a laser device configured to radiate the pulse laser light toward the target having passed through the first region; and a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

### CROSS-REFERENCE TO RELATED APPLICATIONS

The present application claims the benefit of Japanese Patent Application No. 2024/201566, filed on Nov. 19, 2024, the entire contents of which are hereby incorporated by reference.

### BACKGROUND

### 1. Technical Field

The present disclosure relates to an extreme ultraviolet light generation system and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: International Publication No. WO2016/079810
Patent Document 2: International Publication No. WO2014/189055
Patent Document 3: International Publication No. WO2017/130443

### SUMMARY

An extreme ultraviolet light generation system according to an aspect of the present disclosure is an extreme ultraviolet light generation system configured to generate extreme ultraviolet light by irradiating targets with pulse laser light. The extreme ultraviolet light generation system includes a chamber; a target supply unit configured to continuously generate the targets at a specific time interval and supply the targets into the chamber; a timing sensor configured to detect the target passing through a first region and output a signal; a laser device configured to radiate the pulse laser light toward the target having passed through the first region; and a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

An electronic device manufacturing method according to another aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system is configured to generate the extreme ultraviolet light by irradiating targets with pulse laser light. The extreme ultraviolet light generation system includes a chamber; a target supply unit configured to continuously generate the targets at a specific time interval and supply the targets into the chamber; a timing sensor configured to detect the target passing through a first region and output a signal; a laser device configured to radiate the pulse laser light toward the target having passed through the first region; and a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

An electronic device manufacturing method according to another aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system is configured to generate the extreme ultraviolet light by irradiating targets with pulse laser light. The extreme ultraviolet light generation system includes a chamber; a target supply unit configured to continuously generate the targets at a specific time interval and supply the targets into the chamber; a timing sensor configured to detect the target passing through a first region and output a signal; a laser device configured to radiate the pulse laser light toward the target having passed through the first region; and a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

### BRIEF DESCRIPTION OF THE DRAWINGS

Embodiments of the present disclosure will be described below merely as examples with reference to the accompanying drawings.

FIG. 1 schematically shows the configuration of an LPP EUV light generation system.

FIG. 2 shows the configuration of an EUV light generation apparatus according to a comparative example.

FIG. 3 shows an example of an image formed on a light receiving surface of an optical sensor of a target passage detection device.

FIG. 4 shows an example of a detection signal output from the target passage detection device and an example of a target detection trigger signal generated from the detection signal.

FIG. 5 shows an example of the generation cycle timing of each trigger signal generated by a trigger selection and delay device of the comparative example.

FIG. 6 shows an example of the generation timing of each trigger signal generated by the trigger selection and delay device of the comparative example.

FIG. 7 is a flowchart of operation of the EUV light generation apparatus according to the comparative example.

FIG. 8 is a flowchart of a subroutine of the process of timing adjustment A to be applied in step S25 of FIG. 7.

FIG. 9 schematically shows an example of an image acquired via an image sensor of the comparative example.

FIG. 10 shows the generation cycle timing of each trigger signal generated by the trigger selection and delay device of the comparative example.

FIG. 11 shows the configuration of the EUV light generation apparatus according to a first embodiment.

FIG. 12 schematically shows a target passing through a detection region of a timing sensor.

FIG. 13 shows an example of a sensor signal output from the timing sensor and an example of a DL passage signal generated from the sensor signal.

FIG. 14 shows the relationship between a distance from a nozzle to the timing sensor and the N−1th and Nth droplets.

FIG. 15 shows the relationship among a distance from the nozzle to the timing sensor, a distance from the timing sensor to a plasma generation region, and the N−1th and Nth droplets.

FIG. 16 is a flowchart showing an example of the operation of the EUV light generation apparatus according to the first embodiment.

FIG. 17 is a flowchart showing a subroutine of the process of timing adjustment B to be applied in step S15 of FIG. 16.

FIG. 18 is a graph showing an example of a delay time of a laser irradiation timing adjusted through the timing adjustment A and the timing adjustment B of the EUV light generation apparatus.

FIG. 19 shows the configuration of the EUV light generation apparatus according to a second embodiment.

FIG. 20 is a flowchart showing an example of the operation of the EUV light generation apparatus according to the second embodiment.

FIG. 21 is a flowchart showing a subroutine of the process of timing adjustment C to be applied in step S16 of FIG. 20.

FIG. 22 shows the configuration of the EUV light generation apparatus according to a third embodiment.

FIG. 23 is a flowchart showing an example of the operation of the EUV light generation apparatus according to the third embodiment.

FIG. 24 is a flowchart showing a subroutine of the process of timing adjustment D to be applied in step S18 of FIG. 23.

FIG. 25 schematically shows the configuration of an exposure apparatus connected to the EUV light generation apparatus.

FIG. 26 schematically shows the configuration of an inspection apparatus connected to the EUV light generation apparatus.

### DESCRIPTION OF EMBODIMENTS

### Contents

1. Description of terms
2. Overall description of EUV light generation system
   2.1 Configuration
   2.2 Operation
3. EUV light generation apparatus according to comparative example
   3.1 Configuration
   3.2 Operation
4. Problem
5. First Embodiment
   5.1 Configuration
   5.2 Outline of timing adjustment B
   5.3 Time interval I₀
   5.4 Time deviation dT_{1,N}
   5.5 Operation
   5.6 Effect
   5.7 Others
6. Second Embodiment
   6.1 Configuration
   6.2 Operation
   6.3 Effect
7. Third Embodiment
   7.1 Configuration
   7.2 Operation
   7.3 Effect
8. Electronic device manufacturing method
9. Processor
10. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

A “target” is an object to be irradiated with laser light introduced into a chamber. The target irradiated with laser light is turned into plasma and emits EUV light.

A “droplet” is a form of a target supplied into the chamber. “DL” is an abbreviation for droplet.

“Plasma light” is radiation light radiated from a target turned into plasma. The radiation light includes EUV light.

### 2. Overall Description of EUV Light Generation System

### 2.1 Configuration

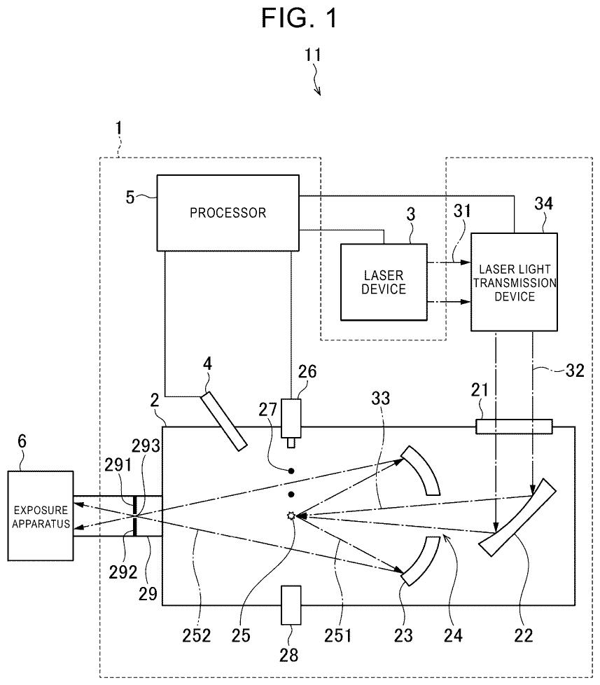

FIG. 1 schematically shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11.

The EUV light generation apparatus 1 includes a chamber 2 and a target supply unit 26. The chamber 2 is a sealable container. The target supply unit 26 supplies a target substance into the chamber 2. The material of the target substance may include tin, terbium, gadolinium, lithium, xenon, or a combination of any two or more thereof.

A through hole is formed in a wall of the chamber 2. The through hole is blocked by a window 21 through which pulse laser light 32 output from the laser device 3 passes. An EUV light concentrating mirror 23 having a spheroidal reflection surface is arranged in the chamber 2. The EUV light concentrating mirror 23 has a first focal point and a second focal point. A multilayer reflection film in which molybdenum and silicon are alternately stacked is formed on a surface of the EUV light concentrating mirror 23. The EUV light concentrating mirror 23 may be arranged so that the first focal point is located in a plasma generation region 25 and the second focal point is located at an intermediate focal point 293. A through hole 24 is formed at the center of the EUV light concentrating mirror 23, and pulse laser light 33 passes through the through hole 24.

The EUV light generation apparatus 1 includes a processor 5, a target sensor 4, and the like. The target sensor 4 detects at least one of the presence, trajectory, position, and velocity of the target 27. The target sensor 4 may have an imaging function.

Further, the EUV light generation apparatus 1 includes a connection portion 29 providing communication between the internal space of the chamber 2 and the internal space of the exposure apparatus 6. A wall 291 in which an aperture 292 is formed is provided in the connection portion 29. The wall 291 is arranged so that an opening of the aperture 292 is located at the second focal point of the EUV light concentrating mirror 23.

Further, the EUV light generation apparatus 1 includes a laser light transmission device 34, a laser light concentrating mirror 22, a target collection device 28 for collecting the target 27, and the like. The laser light transmission device 34 includes an optical element for defining a transmission state of laser light, and an actuator for adjusting the position, posture, and the like of the optical element.

### 2.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The target supply unit 26 outputs the target 27 formed of a target substance toward the plasma generation region 25 in the chamber 2. The target 27 is irradiated with the pulse laser light 33. The target 27 irradiated with the pulse laser light 33 is turned into plasma, and radiation light 251 is radiated from the plasma. EUV light 252 contained in the radiation light 251 is selectively reflected by the EUV light concentrating mirror 23. The EUV light 252 reflected by the EUV light concentrating mirror 23 is concentrated at the intermediate focal point 293 and output to the exposure apparatus 6. Here, one target 27 may be irradiated with a plurality of pulses included in the pulse laser light 33.

The processor 5 is configured to control the entire EUV light generation system 11. The processor 5 processes image data or the like of the target 27 captured by the target sensor 4. The processor 5 performs, for example, at least one of control of the timing at which the target 27 is output and control of the output direction of the target 27, and the like. Further, the processor 5 performs, for example, at least one of control of the oscillation timing of the laser device 3, control of the travel direction of the pulse laser light 32, and control of the concentration position of the pulse laser light 33. The above-described various kinds of control are merely examples, and other control may be added as necessary.

### 3. EUV Light Generation Apparatus According to Comparative Example

### 3.1 Configuration

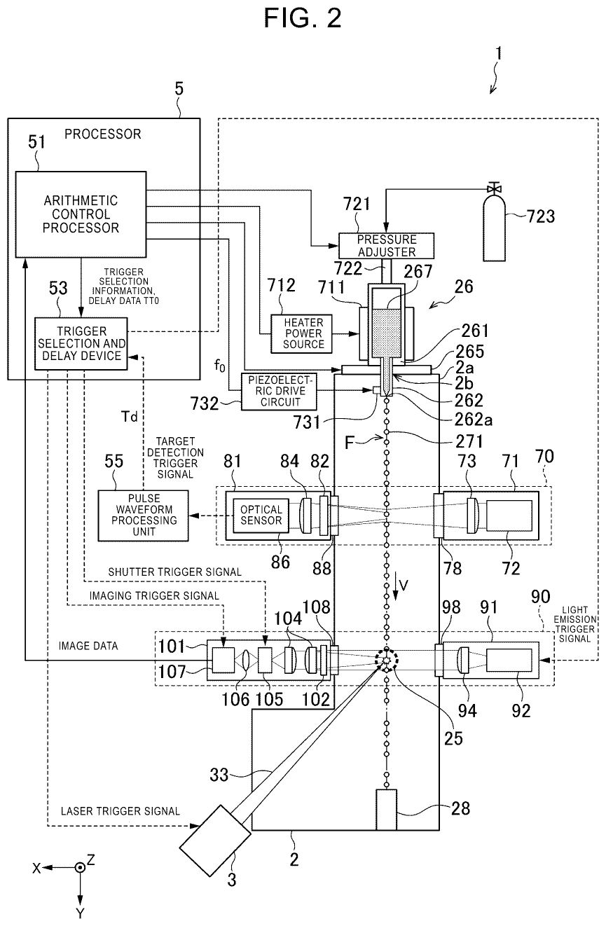

The configuration of the EUV light generation apparatus 1 according to the comparative example will be described using FIG. 2. The comparative example of the present disclosure is an example recognized by the applicant as known only by the applicant, and is not a publicly known example admitted by the applicant.

In FIG. 2, the direction in which the EUV light 252 is introduced from the chamber 2 of the EUV light generation apparatus 1 toward the exposure apparatus 6 (not shown in FIG. 2) is defined as a Z axis. An X axis and a Y axis are orthogonal to the Z axis and orthogonal to each other. In the subsequent drawings, the same coordinate axes as those introduced in FIG. 2 are used.

The chamber 2 is formed in a hollow spherical shape or a cylindrical shape, for example. The center axis direction of the cylindrical chamber 2 may be a Z-axis direction. In FIG. 2, illustration of the laser light concentrating mirror 22 (see FIG. 1) is omitted, and a state in which the pulse laser light 33 output from the laser device 3 is radiated toward the plasma generation region 25 is described for convenience. The description in FIG. 1 is not a description for specifying the irradiation direction of the pulse laser light 33. The irradiation direction of the pulse laser light 33 may be the Z-axis direction.

The chamber 2 is provided with a target supply path 2a for supplying the target 27 from outside the chamber 2 into the chamber 2. The target supply path 2a is formed into a cylindrical shape. The center axis direction of the cylindrical target supply path 2a may be substantially perpendicular to the Z axis. The center axis direction of the target supply path 2a shown in FIG. 2 is the Y direction.

When the chamber 2 has a hollow spherical shape, the target supply path 2a may be provided in a wall portion of the chamber 2 at a position where the window 21 and the connection portion 29 are not arranged. The target supply path 2a communicating with the chamber 2 may be understood as a part of the chamber 2, and the inside of the target supply path 2a is understood as the inside of the chamber 2.

The target supply unit 26 is arranged at an end of the target supply path 2a in the Y direction (an upper end in the Y direction in FIG. 2). The target supply unit 26 includes a tank 261, a nozzle 262, and a piezoelectric element 731. The tank 261 is formed in a hollow cylindrical shape. A target substance 267 is contained in the tank 261.

At least the inner surface of the tank 261 is made of a material that is less likely to react with the target substance 267. The material that is less likely to react with the target substance 267 may be, for example, any of SiC, SiO₂, Al₂O₃, molybdenum, tungsten, and tantalum.

The nozzle 262 is arranged at the bottom surface of the tank 261. One end of the pipe-shaped nozzle 262 is fixed to the hollow tank 261, and the other end is provided with a nozzle hole 262a. The tank 261 is located outside the chamber 2 and the nozzle hole 262a is located inside the chamber 2. That is, the tank 261 is arranged outside the target supply path 2a, and the nozzle 262 is arranged inside the target supply path 2a through the target supply hole 2b of the target supply path 2a. The target supply unit 26 is arranged at the end of the target supply path 2a, so that the target supply hole 2b is blocked. As a result, the inside of the chamber 2 is isolated from the atmosphere. The tank 261, the nozzle 262, the target supply path 2a, and the chamber 2 are in communication with each other.

At least the inner surface of the nozzle 262 is made of a material that is less likely to react with the target substance 267. The nozzle hole 262a is formed in a shape such that the molten target substance 267 is ejected into the chamber 2 in a jet form.

The plasma generation region 25 in the chamber 2 is located on an extension line of the center axis direction of the nozzle 262.

The target supply unit 26 includes a heater 711 and a heater power source 712 as a mechanism for adjusting the temperature of the tank 261. The heater 711 is fixed to an outer side surface portion of the tank 261 and heats the tank 261. The heater 711 is connected to the heater power source 712. The heater power source 712 supplies power to the heater 711.

The processor 5 includes an arithmetic control processor 51 and a trigger selection and delay device 53. The processor 5 functions as an EUV light generation control unit.

The heater power source 712 is connected to the arithmetic control processor 51, and power supply to the heater 711 is controlled by the arithmetic control processor 51.

A temperature sensor (not shown) is fixed to the outer side surface portion of the tank 261. The temperature sensor is connected to the arithmetic control processor 51. The temperature sensor detects the temperature of the tank 261 and outputs a detection signal to the arithmetic control processor 51. In order to heat and maintain the target substance 267 in the tank 261 to and at a predetermined temperature equal to or higher than the melting point, the arithmetic control processor 51 may adjust the power to be supplied to the heater 711 based on the detection signal from the temperature sensor. When the target substance 267 is tin, the predetermined temperature is equal to or higher than 231.93° C. being the melting point of tin and, for example, is 240° C. or higher and 290° C. or lower. The arithmetic control processor 51 controls the temperature of the target substance 267 to the predetermined temperature by adjusting a value of the current to be supplied from the heater power source 712 to the heater 711 based on an output from the temperature sensor.

The target supply unit 26 includes a pressure adjuster 721 that adjusts the pressure in the tank 261. The pressure adjuster 721 is connected to the tank 261 through a pipe 722. The pipe 722 may be covered with a heat insulating material (not shown) or the like. A heater (not shown) may be arranged at the pipe 722. The inside of the pipe 722 may be maintained at substantially the same temperature as the temperature in the tank 261.

As described above, the pressure adjuster 721 is provided through a pipe 722 on a bottom surface portion of the cylindrical tank 261 on the opposite side to the nozzle 262.

The pressure adjuster 721 includes a solenoid valve for supplying and exhausting, a pressure sensor, and the like. The pressure adjuster 721 may detect the pressure in the tank 261 using the pressure sensor.

The pressure adjuster 721 is connected to a gas cylinder 723. The gas cylinder 723 is filled with an inert gas such as helium or argon. The gas cylinder 723 supplies the inert gas into the tank 261 through the pressure adjuster 721.

The pressure adjuster 721 is connected to an exhaust pump (not shown). The pressure adjuster 721 can operate the exhaust pump to exhaust gas in the tank 261. The pressure adjuster 721 can increase or decrease the pressure in the tank 261 by supplying gas into the tank 261 or exhausting gas from the 261.

The pressure adjuster 721 is connected to the arithmetic control processor 51. The pressure adjuster 721 outputs a detection signal of the pressure detected by the pressure sensor to the arithmetic control processor 51. The pressure adjuster 721 receives a control signal output from the arithmetic control processor 51.

The control signal output from the arithmetic control processor 51 may be a control signal for controlling the operation of the pressure adjuster 721 based on the detection signal output from the pressure adjuster 721 so that the pressure in the tank 261 becomes a target pressure.

The pressure adjuster 721 supplies gas into the tank 261 or exhausts gas in the tank 261 based on the control signal from the arithmetic control processor 51. Accordingly, the pressure in the tank 261 can be adjusted to the target pressure.

The target supply unit 26 forms the droplet 271 by, for example, a continuous jet method. In the continuous jet method, the nozzle 262 is vibrated to give standing waves to the flow of the target 27 ejected in a jet form, thereby periodically separating the target 27. The separated target 27 may form a free interface by its surface tension to form the droplet 271.

The piezoelectric element 731 as a means for vibrating the nozzle 262 is fixed to an outer side surface portion of the pipe-shaped nozzle 262. The target supply unit 26 includes a piezoelectric drive circuit 732, and the piezoelectric element 731 is connected to the piezoelectric drive circuit 732. The piezoelectric drive circuit 732 supplies power to the piezoelectric element 731. The piezoelectric drive circuit 732 is connected to the arithmetic control processor 51. The arithmetic control processor 51 controls power supply to the piezoelectric element 731.

The flow of the target substance 267 ejected in a jet form from the nozzle 262 is periodically separated by the vibration of the piezoelectric element 731 to form the droplets 271.

The piezoelectric drive circuit 732 causes the piezoelectric element 731 to vibrate at a frequency f₀ to generate droplets 271 at 1/f₀ cycle. The frequency f₀ for driving the piezoelectric element 731 is referred to as a “piezoelectric frequency f₀”. The piezoelectric frequency f₀ is a droplet generation frequency, and may be referred to as a target generation frequency. The piezoelectric frequency f₀ is, for example, about 200 kHz, and the droplet generation cycle (1/f₀ cycle) is, for example, about 0.005 ms. The piezoelectric frequency f₀ is an example of the “vibration frequency” in the present disclosure. Here, 1/f₀ corresponds to a time interval I₀ of target generation described below.

The description of the target 27 includes the concept of the droplet 271. A trajectory on which the target 27 output from the nozzle 262 moves toward the plasma generation region 25 is referred to as a target trajectory F. A direction in which the target 27 moves toward the plasma generation region 25 is referred to as a “target travel direction”. The target travel direction in FIG. 2 is the Y direction.

The target supply unit 26 is fixed to a stage 265 arranged at an end of the target supply path 2a. The stage 265 can move the target supply unit 26 in two axis directions being the X direction and the Z direction.

The stage 265 is connected to the arithmetic control processor 51. The stage 265 may receive a control signal output from the arithmetic control processor 51.

The control signal output from the arithmetic control processor 51 may be a control signal for adjusting the position of the target supply unit 26 so that the target 27 output into the chamber 2 reaches the target position.

The target collection device 28 is arranged on an extension line in the direction in which the target 27 output into the chamber 2 travels.

The EUV light generation apparatus 1 includes a target passage detection device 70, a target image measurement device 90, and a pulse waveform processing unit 55. Each of the target passage detection device 70 and the target image measurement device 90 is an example of the target sensor 4.

The target passage detection device 70 detects the target 27 passing through a predetermined region in the chamber 2. The predetermined region for monitoring the passage of the target 27 is a region located between the nozzle hole 262a and the plasma generation region 25 and intersecting the target trajectory F.

The target passage detection device 70 is provided at a predetermined position on the side surface portion of the target supply path 2a. The target passage detection device 70 is located between the target supply unit 26 and the plasma generation region 25.

The target passage detection device 70 includes an illumination unit 71 and a measurement instrument 81. The illumination unit 71 and the measurement instrument 81 may be arranged to face each other across the target trajectory F. In FIG. 2, the direction in which the illumination unit 71 and the measurement instrument 81 face each other is substantially parallel to the X direction, but the present invention is not limited thereto.

The illumination unit 71 irradiates the droplet 271 traveling along the target trajectory F with illumination light, which is continuous light. The continuous light applied to the droplet 271 may be continuous laser light.

The illumination unit 71 includes an illumination light source 72, an illumination optical system 73, and a window 78. The window 78 is attached to the wall of the chamber 2. The illumination unit 71 is arranged outside the chamber 2 via the window 78. The illumination light source 72 may be, for example, a light source that outputs continuous laser light such as a continuous wave (CW) laser output unit. The beam diameter of the continuous laser light may be sufficiently larger than the diameter (e.g., 20 μm) of the droplet 271.

The illumination optical system 73 includes an optical element such as a lens. Not limited to a transmissive optical element such as a lens, the optical element may be a reflective optical element such as a mirror, or a combination thereof.

The illumination optical system 73 may include, for example, a cylindrical lens. The illumination optical system 73 may irradiate the target trajectory F with an elliptical beam. The length of the minor axis of the elliptical beam may be a length close to the diameter of the droplet 271, and the major axis may be in a direction perpendicular to the target trajectory F. For example, the minor axis direction of the elliptical beam may coincide with the Y direction, and the major axis direction may coincide with the Z direction. Note that the beam shape of the continuous laser light radiated from the illumination unit 71 may be a shape different from an ellipse.

The illumination optical system 73 concentrates the continuous laser light radiated from the illumination light source 72 through the window 78 into a predetermined region including a target passage detection position on the target trajectory F. The predetermined region including the light concentration region of the illumination optical system 73 is referred to as a “target detection region”. The target detection region is an example of the “first region” in the present disclosure.

When the droplet 271 traveling along the target trajectory F reaches the target detection region, the continuous laser light radiated from the illumination unit 71 illuminates the droplet 271.

The measurement instrument 81 receives the light radiated from the illumination unit 71 and detects the light intensity. The measurement instrument 81 includes a window 88, a filter 82, an imaging optical system 84, and an optical sensor 86. The window 88 is attached to the wall of the chamber 2. The measurement instrument 81 is arranged outside the chamber 2 via a window 88.

The imaging optical system 84 may be an optical system such as a collimator, and is configured by an optical element such as a lens. The imaging optical system 84 guides the continuous laser light radiated from the illumination unit 71 to the optical sensor 86 through the window 88 and the filter 82.

The optical sensor 86 may be a light receiving element including a photodiode. The optical sensor 86 may be a photodiode array including a plurality of sensor elements.

When the droplet 271 passes through the predetermined region of the target trajectory F, a part of the continuous laser light is blocked by the droplet 271, and the light intensity (received light amount) received by the measurement instrument 81 decreases. The measurement instrument 81 outputs a detection signal corresponding to a change in light intensity caused by the passage of the droplet 271 to the pulse waveform processing unit 55. Here, the detection signal corresponding to a change in light intensity obtained from the optical sensor 86 may be referred to as a “target passage detection signal”.

The pulse waveform processing unit 55 receives the target passage detection signal output from the target passage detection device 70, and generates a target detection trigger signal from the target passage detection signal. The target detection trigger signal is a signal indicating a timing at which the target 27 has passed through the predetermined region of the target trajectory F.

The pulse waveform processing unit 55 outputs the target detection trigger signal to the trigger selection and delay device 53. Thus, the trigger selection and delay device 53 may detect the timing at which the target 27 traveling from the target supply unit 26 toward the plasma generation region 25 has passed through the predetermined region on the target trajectory F. The target passage detection device 70 is also referred to as a “timing sensor”. The pulse waveform processing unit 55 may be included in the processor 5.

The target image measurement device 90 captures an image of the target 27 supplied to the plasma generation region 25, and generates image data thereof. The target image measurement device 90 includes an illumination unit 91 and a measurement instrument 101. The illumination unit 91 and the measurement instrument 101 may be arranged to face each other with the target trajectory F interposed therebetween.

The direction in which the illumination unit 91 and the measurement instrument 101 face each other may be substantially perpendicular to the target trajectory F or may be non-perpendicular thereto.

The illumination unit 91 irradiates the target 27 traveling along the target trajectory F with pulse light. The illumination unit 91 includes a flash lamp 92, an illumination optical system 94, and a window 98. The window 98 is attached to the wall of the chamber 2. The illumination unit 91 is arranged outside the chamber 2 via the window 98.

The flash lamp 92 is connected to the trigger selection and delay device 53. The flash lamp 92 emits pulse light pulsed based on the light emission trigger signal output from the trigger selection and delay device 53.

The illumination optical system 94 may be an optical system such as a collimator, and is configured by an optical element such as a lens. The illumination optical system 94 guides the pulse light emitted from the flash lamp 92 onto the target trajectory F through the window 98.

The illumination unit 91 may radiate the pulse light toward the target trajectory F based on the light emission trigger signal. The pulse light radiated from the illumination unit 91 is radiated to the target 27 traveling along the target trajectory F.

The measurement instrument 101 captures an image of the shadow of the target 27 irradiated with the pulse light by the illumination unit 91. The measurement instrument 101 includes a window 108, a filter 102, an imaging optical system 104, a shutter 105, an imaging optical system 106, and an image sensor 107. The window 108 is attached to the wall of the chamber 2. The measurement instrument 101 is arranged outside the chamber 2 via the window 108.

The imaging optical system 104 may be an optical element such as a pair of lenses. The shutter 105 may be an electrical shutter or a mechanical shutter. The shutter 105 is connected to the trigger selection and delay device 53. The shutter 105 opens and closes when the shutter trigger signal output from the trigger selection and delay device 53 is input, and regulates the exposure time of the image sensor 107.

The shutter 105 may be, for example, an image intensifier (IIU) capable of performing gate operation. The image intensifier includes a photoelectric surface, a microchannel plate (MCP), and a fluorescent surface. The photoelectric surface converts light into electrons. The MCP is an electron multiplication element that two-dimensionally detects electrons output from the photoelectric surface and doubles the electrons. The gain can be adjusted by adjusting the voltage to be applied to the MCP. The fluorescent surface converts the electrons output from the output end of the MCP into light.

The gate operation of the image intensifier is achieved by changing the potential difference between the photoelectric surface and the input surface of the MCP. The gate operation is synonymous with shutter operation. When the potential of the photoelectric surface is lower than the potential of the input surface of the MCP, the electrons output from the photoelectric surface enter the MCP, and an output image is obtained from the fluorescent surface. The state of the gate ON corresponds to the state of “shutter open”. Further, when the potential of the photoelectric surface is higher than the potential of the input surface of the MCP, the electrons do not reach the MCP, so that no output image is obtained from the fluorescent surface. The state of the gate OFF corresponds to a state of “shutter closed”. For example, the gate operation can be performed by fixing the potential of the input surface of the MCP and applying a negative pulse voltage to the photoelectric surface.

The imaging optical system 104 and the imaging optical system 106 form an image of the shadow of the target 27 guided through the window 108 on the light receiving surface of the image sensor 107.

The image sensor 107 may be, for example, a two-dimensional image sensor such as a complementary metal oxide semiconductor (CMOS). The image sensor 107 captures an image of the shadow of the target 27 imaged by the imaging optical systems 104, 106.

The image sensor 107 is connected to the trigger selection and delay device 53 and the arithmetic control processor 51. The image sensor 107 captures the image of the shadow of the target 27 based on an imaging trigger signal from the trigger selection and delay device 53. The image sensor 107 may include a signal processing circuit that generates digital image data such as bitmap data from an image signal obtained by imaging.

The image data generated by using the image sensor 107 is transmitted to the arithmetic control processor 51.

The arithmetic control processor 51 calculates parameters related to the target 27 based on the image data obtained from the image sensor 107. Examples of the parameters related to the target 27 may include the size, velocity, position, and target-to-target distance (interval) of the target 27. The target image measurement device 90 is also referred to as a “size sensor”.

The interval of the target 27 is a distance between two adjacent targets 27 sequentially output from the target supply unit 26 into the chamber 2, and is the target-to-target distance in the target travel direction.

The measurement instrument 101 may observe a specific range on the target trajectory F at a fixed point. The position of the droplet 271 imaged by the measurement instrument 101 in the Y direction may be a relative position within the imaging range in the target travel direction. In the captured image, the position of the target 27 in the Y direction may be the position of the target 27 in a direction substantially parallel to the target travel direction.

The trigger selection and delay device 53 generates various trigger signals based on the target detection trigger signal received from the pulse waveform processing unit 55. The trigger selection and delay device 53 adds appropriate delay times to the target detection trigger signal, and generates the imaging trigger signal, the shutter trigger signal, the light emission trigger signal, and the laser trigger signal.

The laser trigger signal is a signal for controlling the irradiation timing of the pulse laser light 33 of the laser device 3.

Further, the trigger selection and delay device 53 generates a target detection trigger signal for EUV light emission and a target detection trigger signal for image measurement by decimating the target detection trigger signals. The target detection trigger signal for EUV light emission is a signal for controlling the timing of generating EUV light. The target detection trigger signal image measurement is a signal for controlling the timing at which the target image measurement device 90 performs target measurement.

The arithmetic control processor 51 transmits trigger selection information and delay data to the trigger selection and delay device 53. The trigger selection information includes information for selecting a trigger signal. The delay data includes information of a delay time required for generation of a corresponding trigger signal.

### 3.2 Operation

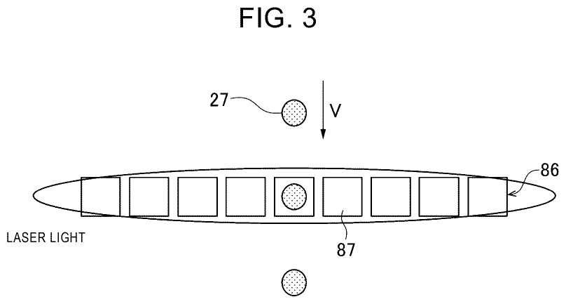

The operation of the target passage detection device 70 and the operation related to the trigger signal generation processing will be described with reference to FIGS. 3 to 6. FIG. 3 shows an example of an image formed on the light receiving surface of the optical sensor 86 of the target passage detection device 70. The optical sensor 86 may be, for example, a photodiode array (PDA) module including a plurality of sensor elements 87. The shape of the light receiving surface of each of the plurality of sensor elements 87 may be a square or may be another shape such as a rectangle. Although FIG. 3 shows a PDA module in which nine sensor elements 87 are arranged in a row, the number and arrangement of the sensor elements 87 are not limited to the example shown in FIG. 3. The sensor element 87 is understood to be a pixel that performs photoelectric conversion.

An image of the elliptical beam of the laser light as illumination light may be incident over the entire sensor elements 87. As the target 27 passes through the light concentration region of the elliptical beam, a shadow of the target 27 may be created on any of the plurality of sensor elements 87.

The diameter of the shadow of the target 27 may be smaller than the length of the side of the light receiving surface of the sensor element 87. The shadow of the target 27 may be an enlarged image of the target 27. The alignment direction of the plurality of sensor elements 87 may be substantially perpendicular to the target travel direction. Further, the arrangement direction of the plurality of sensor elements 87 may be substantially perpendicular to the normal direction of the light receiving surface. The normal direction of the light receiving surface may substantially coincide with the direction in which the laser light is incident.

In FIG. 3, the shadow of the target 27 passes through the light receiving surface of the sensor element 87 located in the center of the PDA module. The downward arrow in FIG. 3 indicates the target travel direction, and a velocity V of the target 27 is, for example, 45 m/s.

The movement direction of the shadow of the target 27 on the light receiving surface is determined by the positional relationship between the direction in which the illumination light is incident on the light receiving surface and the target trajectory F. Therefore, the movement direction of the shadow of the target 27 on the light receiving surface may not coincide with the movement direction of the target 27.

The target passage detection device 70 radiates the continuous laser light having a sheet-like shape (elliptical beam shape) from the illumination unit 71 so as to pass through a position above the plasma generation region 25 by 2.5 mm. Here, the position above the plasma generation region 25 means the position on the upstream side of the target trajectory F in the target travel direction, that is, the position on the side close to the target supply unit 26.

The position above the plasma generation region 25 by 2.5 mm is an example of the position set as the target detection region. The laser light having passed through the position above the plasma generation region 25 by 2.5 mm passes through the imaging optical system 84 and enters the PDA module.

The imaging optical system 84 forms an image of the predetermined region including the position above the plasma generation region 25 by 2.5 mm on the sensor surface of the PDA module.

When the droplet 271 is not present in the target detection region, the laser light enters the PDA module without being blocked, and the PDA module outputs a constant detection signal corresponding to the light receiving amount. Here, the signal level of the “constant detection signal” is defined as the signal strength “100%”.

When the droplet 271 discharged at the frequency f₀ (about 200 kHz) passes through the target detection region of the target passage detection device 70, the detection signal output from the PDA module decreases.

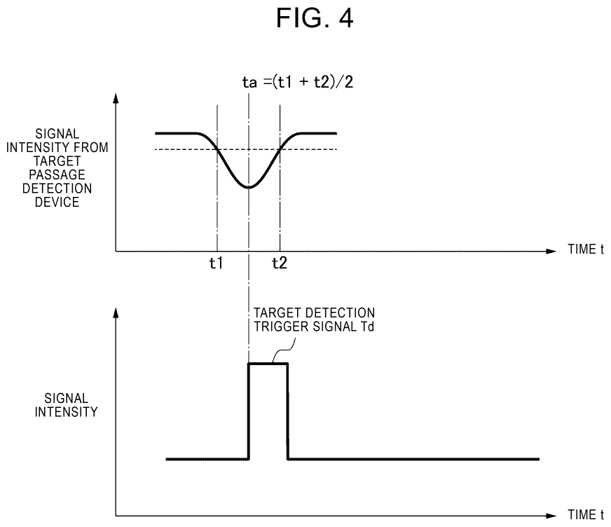

FIG. 4 shows an example of the detection signal output from the target passage detection device 70 and an example of a target detection trigger signal Td generated from the detection signal.

As shown at the upper stage of FIG. 4, the signal intensity of the detection signal output from the target passage detection device 70 decreases due to the passage of the target 27. When the target 27 moves out of the target detection region, the signal intensity of the detection signal recovers to the original 100% level.

The pulse waveform processing unit 55 uses the level at which the signal intensity of the detection signal is 100% as a reference, and detects a midpoint of t1 and t2 as the passage timing of the target 27, where t1 represents the time at which the detection signal has decreased to a threshold set to a constant ratio with respect to the reference intensity and t2 represents the time at which the decreased detection signal has recovered to the threshold. That is, when the passage timing is ta, ta is calculated by the following expression.

ta=(t1+t2)/2

The time t1 is referred to as a “signal drop timing”, and the time t2 is referred to as a “signal recovery timing”. The threshold may be set to 90% of the reference intensity, for example. The dashed line in the graph at the upper stage of FIG. 4 indicates the level of the threshold.

As shown at the lower stage of FIG. 4, the pulse waveform processing unit 55 outputs the target detection trigger signal Td with reference to the time ta. In FIG. 4, the target detection trigger signal Td is generated and output at the timing of ta=Td.

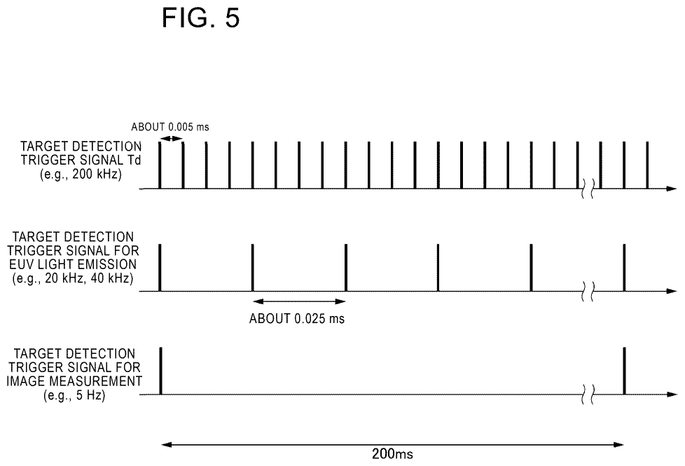

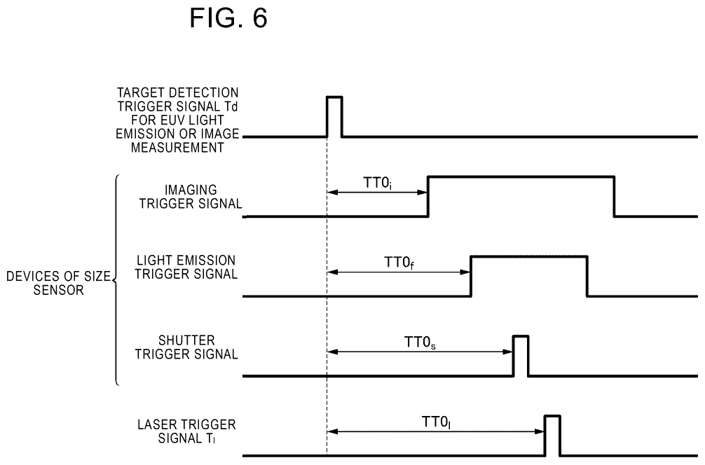

FIGS. 5 and 6 show examples of the generation cycle timing and the generation timing of trigger signals generated by the trigger selection and delay device 53. The target detection trigger signal Td is shown at the upper stage of FIG. 5, the target detection trigger signal for EUV light emission is shown at the middle stage, and the target detection trigger signal for image measurement is shown at the lower stage as examples.

The target detection trigger signal Td is generated, for example, for each of the droplets 271 generated at a 200 kHz level.

The trigger selection and delay device 53 receives the trigger selection information from the arithmetic control processor 51, and performs operation 1 and operation 2 described below based on the target detection trigger signal Td.

[Operation 1] Since the EUV light emission is performed, for example, at a 20 kHz or 40 kHz level, the trigger selection and delay device 53 generates the target detection trigger signal for EUV light emission by decimating the target detection trigger signal Td to have that frequency.

[Operation 2] Since the measurement of the target 27 by the target image measurement device 90 is performed, for example, at time intervals of about 200 ms (at a 5 Hz level), the trigger selection and delay device 53 further decimates the target detection trigger signal for EUV light emission and generates the target detection trigger signal for image measurement.

FIG. 6 shows an example of the respective trigger signals being the target detection trigger signal Td for EUV light emission or image measurement, the imaging trigger signal, the light emission trigger signal, the shutter trigger signal, and a laser trigger signal T₁ from above.

The trigger selection and delay device 53 receives information of the delay time from the arithmetic control processor 51 and generates various trigger signals.

The information of the delay time received by the trigger selection and delay device 53 includes a delay time TT0₁ to be applied to the imaging trigger signal, a delay time TT0_{f} to be applied to the light emission trigger signal, a delay time TT0ₛ to be applied to the shutter trigger signal, and a delay time TT0₁ to be applied to the laser trigger signal T₁.

The trigger selection and delay device 53 adds the delay time TT01 to the time Td of the target detection trigger signal for EUV light emission to generate the laser trigger signal T₁.

The trigger selection and delay device 53 adds the delay times TT0₁, TT0_{f}, TT0ₛ for operating the target image measurement device 90 based on the image measurement target detection signal to generate the imaging trigger signal, the light emission trigger signal, and the shutter trigger signal, respectively. The delay time (TT0₁, TT0_{f}, TT0ₛ, TT0₁) of each device is determined in consideration of the operation delay time from the time each device receives the trigger signal to start of the operation. The operation delay time is a value specific to each device.

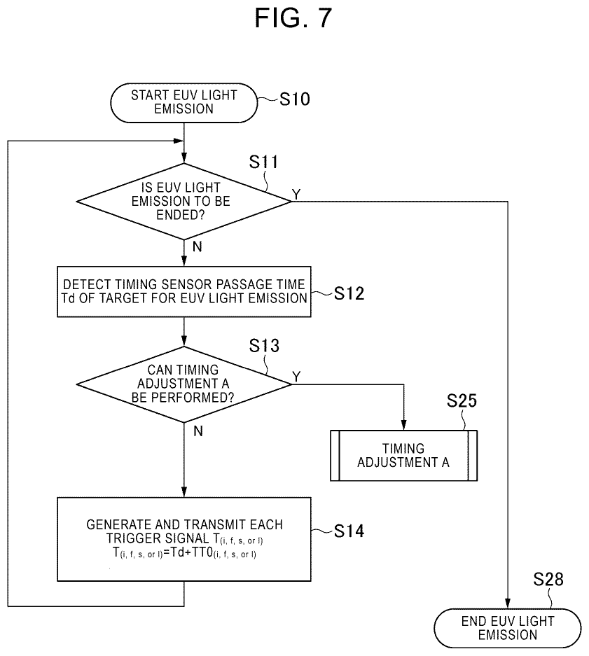

FIG. 7 is a flowchart showing an example of the operation of the EUV light emission.

In step S10, the arithmetic control processor 51 starts the EUV light emission.

In step S11, the arithmetic control processor 51 determines whether or not to end the EUV light emission. When the determination result of step S11 is NO, processing proceeds to step S12.

In step S12, the pulse waveform processing unit 55 detects the timing sensor passage time Td of the target 27 for EUV light emission. As shown in FIG. 4, with respect to the output signal of the timing sensor when the droplet 271 passes through the detection region (target detection region) of the timing sensor, the pulse waveform processing unit 55 detects, as the passage timing of the target, the midpoint ta=(t1+t2)/2 from the time t1 at which the output signal decreases to the set threshold and the time t2 at which the decreased signal is recovered to the threshold.

The pulse waveform processing unit 55 detects the timing of ta=Td as the timing sensor passage time Td, and outputs it to the trigger selection and delay device 53. Instead of obtaining from t1 and t2, the passage timing ta may be obtained as the time point (lower peak point) at which the detection signal of the timing sensor is minimized.

In step S13, the arithmetic control processor 51 determines whether or not timing adjustment A can be performed. The timing adjustment A is a process of adjusting the delay time Tt0_{(i, f, s, or 1)} of the trigger signal based on the acquired image by the target image measurement device 90. The description of “(i, f, s, or 1)” indicates that the suffix is one of “i”, “f”, “s”, and “l”, and may be omitted.

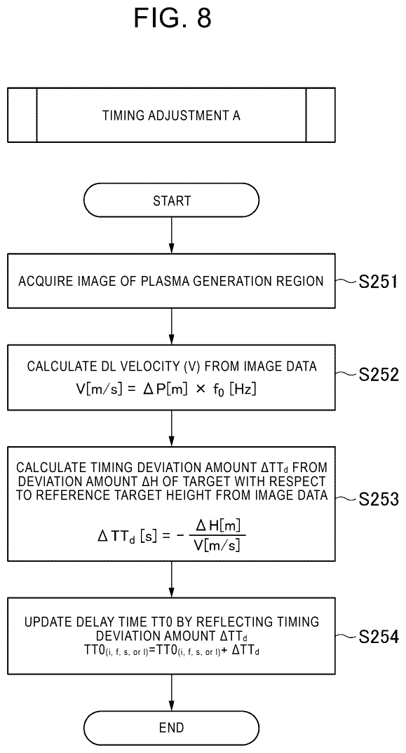

The timing adjustment A is, for example, performed at time intervals of 200 ms, and takes time to be processed. Therefore, in step S13, the arithmetic control processor 51 determines whether or not the timing adjustment A is completed and the next image can be acquired. When acquirable (YES determination), the process of step S14 and the process of the timing adjustment A of step S25 described later are performed in parallel. The subroutine of the timing adjustment A will be described later with reference to FIG. 8.

On the other hand, when it is determined that the execution of the timing adjustment A is not possible (NO determination) in the determination result of step S13, the processor 5 performs the process of step S14 alone.

In step S14, the trigger selection and delay device 53 transmits, to the corresponding device, each trigger signal at a timing T_{(i, f, s, or 1)} obtained by adding the delay time TT0_{(i, f, s, or 1)} to the passage time Td of the target 27.

T_{(f,s, or 1)}=Td+TT0_{(i,f,s, or 1)} (Expression 1)

Here, Tᵢ, T_{f}, and Tₛ represent the timings of the imaging trigger signal, the light emission trigger signal, and the shutter trigger signal in the target image measurement device 90, respectively. Tᵢ is an example of the “imaging timing of the image sensor” in the present disclosure. T_{f} is an example of the “light emission timing of the flash lamp” in the present disclosure. Ts is an example of the “operation timing of the shutter” in the present disclosure.

After step S14, processing returns to step S11.

When the determination result of step S11 is YES, processing proceeds to step S28, and the processor 5 ends the EUV light emission.

FIG. 8 is a flowchart showing an example of the process of the timing adjustment A to be applied in step S25. The timing adjustment A is an adjustment process of the delay time TT0_{(i, f, s, or 1)} by a size sensor performed in parallel with the flow of steps S11 to S14 of FIG. 7.

In step S251, the arithmetic control processor 51 acquires an image of the target 27 in the plasma generation region 25 from the image sensor 107. For detail of the acquiring procedure of the image, the processor 5 provides a trigger signal to the size sensor at the timing shown in FIG. 6 and acquires the image in the following steps [ST1] to [ST5].
[ST1] The image sensor 107 receives the imaging trigger signal generated as being delayed by TT0ᵢ from the target detection trigger signal Td for image measurement, and starts exposure for a certain period of time.
[ST2] The flash lamp 92 receives the light emission trigger signal generated as being delayed by TT0_{f} from the target detection trigger signal Td for image measurement, and emits light for a certain period of time.
[ST3] The light emitted by the flash lamp 92 illuminates the plasma generation region 25, and the light having passed through the plasma generation region 25 reaches the shutter 105 through the imaging optical system 104.
[ST4] The shutter 105 receives the shutter trigger signal generated as being delayed by TT0ₛ from the target detection trigger signal Td for image measurement, and applies a voltage for a certain period of time (the shutter 105 is opened).
[ST5] The light having passed through the shutter 105 passes through the imaging optical system 106 and reaches the image sensor 107. By transferring the image of the plasma generation region 25 onto the image sensor 107 by the two imaging optical systems 104, 106, the image including the image of the shadow of the target 27 in the plasma generation region 25 is output from the image sensor 107.

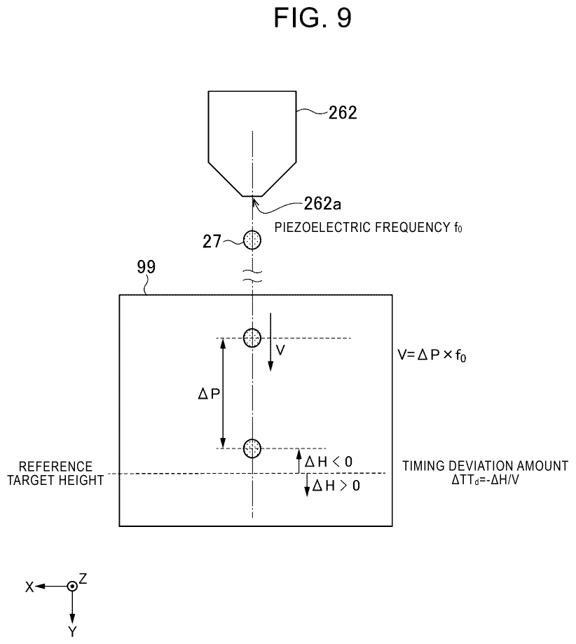

FIG. 9 schematically shows an example of an image 99 acquired via the image sensor 107. The image sensor 107 captures the image 99 including images of shadows of the plurality of targets 27 sequentially output from the nozzle 262. The region including the plasma generation region 25 imaged by the image sensor 107 is an example of the “second region” in the present disclosure.

In step S252 of FIG. 8, the arithmetic control processor 51 reads the image 99 output from the image sensor 107, processes image data to obtain a target interval ΔP on the image 99, and calculates the target velocity V from the target interval ΔP and the piezoelectric frequency f₀ (target generation frequency). The target velocity V is synonymous with the droplet (DL) velocity.

V=ΔP×f₀ (Expression 2)

As specific values, for example, when the target interval ΔP is 225 μm and the piezoelectric frequency f₀ is 200 kHz, the target velocity V is 45 m/s.

Next, in step S253, when the height of the target 27 in the image data is deviated from the reference target height corresponding to the plasma generation region 25, the arithmetic control processor 51 calculates a deviation amount ΔH. The deviation amount ΔH is referred to as “target height deviation ΔH”. Further, the arithmetic control processor 51 calculates a timing deviation amount ΔTT_{d} from the target height deviation ΔH and the target velocity V.

ΔTT_{d}=−ΔH/V (Expression 3)

The unit of the timing deviation amount ΔTT_{d} is seconds (s), the unit of the target height deviation ΔH is meters (m), and the unit of the target velocity V is meters per second (m/s).

Here, the term “height” of the target 27 means a position in the target travel direction (Y direction). The targeted target 27 for which the target height deviation ΔH is calculated is the target 27 closest to the reference target height among the plurality of targets 27 included in the image 99. Here, ΔH is a negative value when the targeted target 27 is on the target supply unit 26 side with respect to the reference target height, and is a positive value when it is on the opposite side (the target collection device 28 side). The Y axis is oriented downward in FIG. 9 and represents the target travel direction. The reference target height is an example of the “reference target position” in the present disclosure.

Here, ΔTT_{d} shown in Expression 3 has a sign opposite to the sign of ΔH. The target height deviation ΔH is generated by a change in the target velocity V.

The timing deviation amount ΔTT_{d} calculated by Expression 3 is the correction amount of the delay time TT0_{(i, f, s, or 1)}.

In step S254, the arithmetic control processor 51 updates the delay time TT0_{(i, f, s, or 1)} by reflecting the timing deviation ΔTT_{d} to the delay time TT0_{(i, f, s, or 1)}.

That is, the arithmetic control processor 51 transmits, to the trigger selection and delay device 53, the delay time TT0_{(i, f, s, or 1)} of each of the triggers for operation of the laser device 3 and the size sensor after correcting by ΔTT_{d}, and completes the parallel processing of the subroutine shown in FIG. 8.

TT0_{(i,f,s, or 1)}=TT0_{(i,f,s, or 1)}+ΔTT_{d} (Expression 4)

The left side of Expression 4 represents the corrected delay time, and TT0_{(i, f, s, or 1)} on the right side represents the current (uncorrected) delay time.

After completion of the timing adjustment A of FIG. 8, the trigger selection and delay device 53 transmits, to the corresponding device, each trigger signal at a timing T_{(i, f, s, or 1)} obtained by adding the delay time TT0_{(i, f, s, or 1)} corrected by Expression 4 in synchronization with the passage time Td of the new target (step S14 of FIG. 7).

That is, the trigger selection and delay device 53 performs operation with the delay time TT0_{(i, f, s, or 1)} fixed until completion of correcting the delay time TT0_{(i, f, s, or 1)} due to the next timing adjustment A.

### 4. Problem

In the EUV light generation apparatus 1 according to the comparative example, the correction of the deviation of the irradiation timing of the pulse laser light 33 due to the velocity change of the target 27 is performed using the processing result of the image 99 obtained by the target image measurement device 90. Therefore, the correction of the timing deviation is performed at the acquisition frequency of the image 99, which is a low frequency of, for example, 5 Hz (at imaging time intervals of 200 ms).

However, the velocity of the target 27 also changes during the imaging interval of 200 ms by the target image measurement device 90, and in the EUV light generation apparatus 1, the deviation of the irradiation timing cannot be sufficiently corrected.

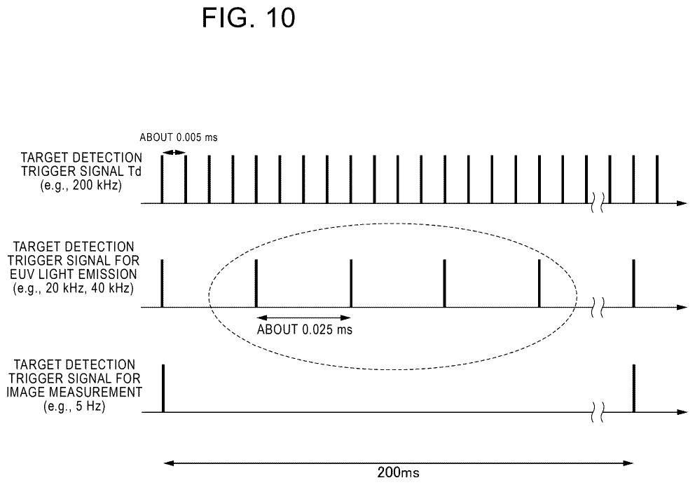

That is, since the target 27 cannot be measured by the target image measurement device 90 during the imaging interval 200 ms as in the period surrounded by a broken line ellipse in FIG. 10, it is not possible to correct the deviation of the irradiation timing caused by the velocity change of the target 27 used for EUV light generation within this period.

The above causes deterioration in EUV light emission performance, such as a decrease in the energy conversion efficiency (Conversion Efficiency: CE) and a variation increase in the EUV light energy. Further, contamination of the EUV light concentrating mirror 23 occurs due to occurrence of fragments caused by the relative positional deviation between the target 27 and the irradiation position of the pulse laser light 33.

### 5. First Embodiment

### 5.1 Configuration

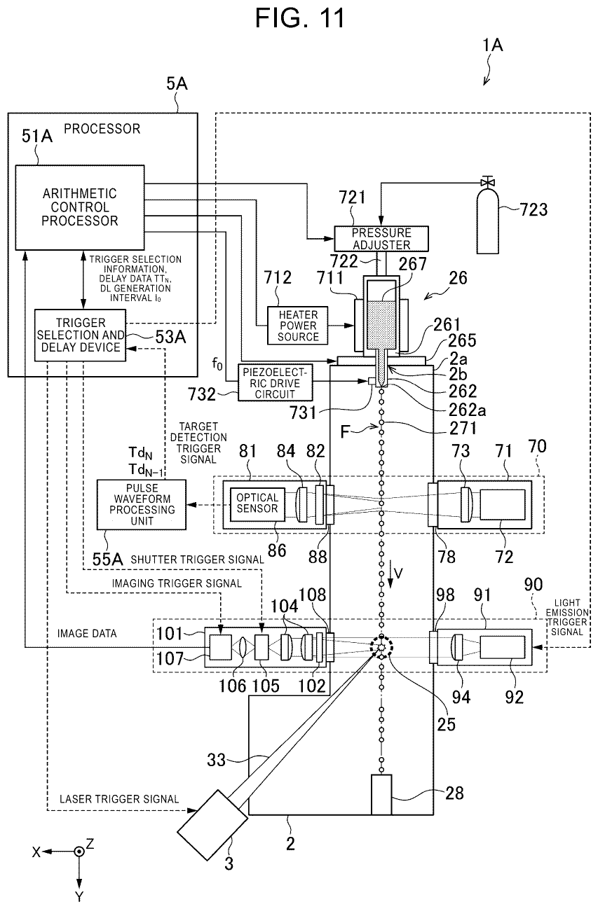

FIG. 11 shows the configuration of an EUV light generation apparatus 1A according to a first embodiment. The configuration of the EUV light generation apparatus 1A shown in FIG. 11 will be described in terms of differences from the configuration of the EUV light generation apparatus 1 shown in FIG. 2.

The EUV light generation apparatus 1A includes a pulse waveform processing unit 55A and a processor 5A instead of the pulse waveform processing unit 55 and the processor 5 of FIG. 2. The processor 5A includes an arithmetic control processor 51A and a trigger selection and delay device 53A. Other configurations are similar to those of the EUV light generation apparatus 1.

The EUV light generation apparatus 1A is different from the EUV light generation apparatus 1 in that the target passage detection device 70 (timing sensor) is used to measure the velocity change of the target 27 and the timing deviation due to the velocity change is corrected. That is, the EUV light generation apparatus 1A performs timing adjustment B to be described below.

### 5.2 Outline of Timing Adjustment B

The trigger selection and delay device 53A receives the time interval I₀ for generating targets from the arithmetic control processor 51A. The time interval I₀ may be the inverse of the frequency f₀ that causes the piezoelectric element 731 of the nozzle 262 to vibrate. By the piezoelectric element 731 vibrating at the frequency f₀, Sn target material discharged from the nozzle 262 is split at the frequency f₀ and spherical droplets are generated by surface tension. Therefore, the time interval I₀ is the inverse of the frequency f₀.

The trigger selection and delay device 53A receives the passage times Td_{N} and Td_{N-1} of the targets detected from the output signal (sensor signal) of the timing sensor from the pulse waveform processing unit 55A, and calculates a time interval I_{N} between Td_{N} and Td_{N-1}.

I_{N}=Td_{N}−Td_{N-1} (Expression 5)

Here, Td_{N} is the passage time of the Nth target 27 detected by the timing sensor. Further, Td_{N-1} is the passage time of the N−1th target 27 detected by the timing sensor. N is an integer of 1 or more. The passage time Td_{N} of the Nth target 27 that is one of the plurality of targets 27 generated continuously at the time interval I₀ is an example of the “first time” in the present disclosure. Further, the N−1th passage time Td_{N-1} of the N−1th target 27 generated immediately before the Nth one is an example of the “second time” in the present disclosure. The time interval I_{N} is an example of the “passage interval” in the present disclosure.

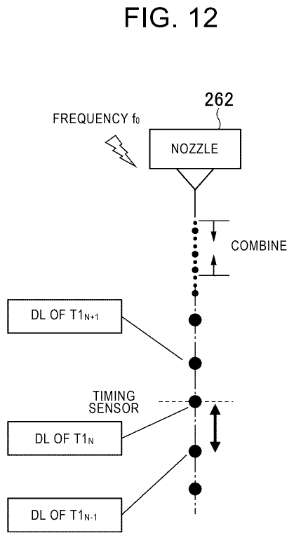

FIG. 12 schematically shows a target passing through the detection region of the timing sensor. The targets 27 sequentially output from the nozzle 262 are detected by the timing sensor, and the passage signal of each target (DL passage signal) is generated by the pulse waveform processing unit 55A.

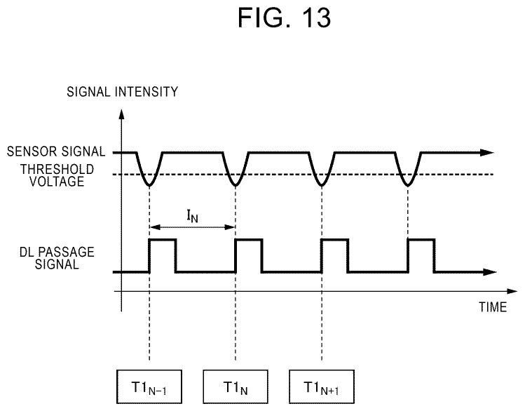

FIG. 13 shows the sensor signal output from the timing sensor and the DL passage signal generated from the sensor signal. The DL passage signal may be understood to be the same as the target detection trigger signal. In FIG. 13, the horizontal axis represents time and the vertical axis represents signal intensity.

In FIG. 13, the target 27 passing through the detection region of the timing sensor at the timing of the time T1_{N} is referred to as the “Nth droplet”. In FIG. 12, the Nth droplet is referred to as “DL of T1_{N}”. The interval between the passage times of the Nth and N−1th droplets is I_{N}.

If there is no variation in the velocity of the targets 27 sequentially output from the nozzle 262, the time interval I_{N} of the DL passage signal is the target generation cycle 1/f₀, that is, the time interval I₀. If the velocity of the target 27 changes, the time interval I_{N} has a value different from the time interval I₀.

The trigger selection and delay device 53A calculates time deviation dT_{1,N} of the time interval I_{N} with respect to the time interval I₀.

dT_{1,N}=I_{N}−I₀ (Expression 6)

The trigger selection and delay device 53A calculates estimated time deviation dT_{2,N} with which the target 27 reaches the plasma generation region 25 estimated from the time deviation dT_{1,N} and adds the estimated time deviation dT_{2,N} to the delay time TT_{N(i, f, s, or 1)} to update the delay time TT_{N(i, f, s, or 1)}. A series of operation of the adjustment of the delay time TT_{N(i, f, s, or 1)} with the estimated time deviation dT_{2,N} is the timing adjustment B.

Then, the trigger selection and delay device 53A applies the updated delay time TT_{N(i, f, s, or 1)}, determines the timing of each trigger signal T_{N(i, f, s, or 1)} by following Expression 7, and transmits it to each device.

T_{N(i,f,s, or 1)}=Td_{N}+TT_{N(i,f,s, or 1)} (Expression 7)

The delay time TT_{N1} is an example of the “first delay time” in the present disclosure.

### 5.3 Time Interval I₀

The time interval I₀ need not be based on the vibration frequency of the piezoelectric element 731 as long as it indicates the time interval of the generated droplets, and may be based on, for example, the vibration frequency or vibration cycle of a voice coil or an ultrasonic wave in a device that generates the target 27 using another vibration transmission component. Further, in a case such as when using means other than vibration, for example, in the target generation device in which the target 27 is drawn from the nozzle 262 using gas pressure or pulse-shaped electric field, a time interval of the frequency of the pressure control or the electric field to be applied may be used.

### 5.4 Time Deviation dT_{1,N}

As described above, the time interval I_{N} of the DL passage signal output from the pulse waveform processing unit 55A is the same as the time interval I₀ of the target generation if there is no variation in the velocity of the N−1th and Nth droplets. Therefore, in this case, the time deviation dT_{1,N} is zero.

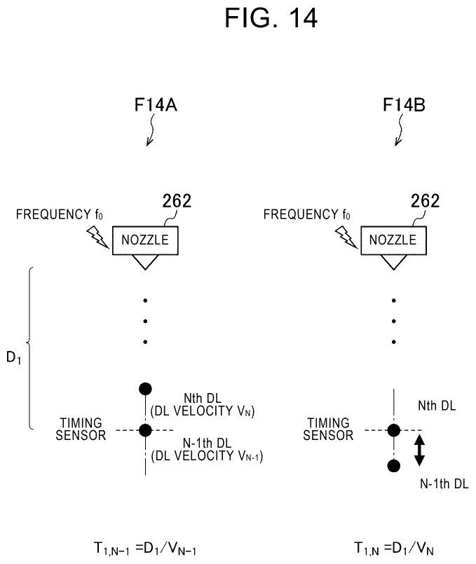

FIG. 14 shows the relationship between a distance D1 from the nozzle 262 to the detection region of the timing sensor and the N−1th and Nth droplets. F14A on the left of FIG. 14 shows the state of the N−1th droplet passing through the detection region of the timing sensor, and F14B on the right thereof shows the state of the Nth droplet passing through the detection region of the timing sensor.

Here, when the velocities of the N−1th and Nth droplets are taken as V_{N-1} and V_{N}, the required times T_{1,N-1} and T_{1,N} for the respective droplets to move by the distance D₁ from the nozzle 262 to the detection region of the timing sensor are as follows.

T_{1,N-1}=D₁/V_{N-1} (Expression 8)

T_{1,N}=D₁/V_{N} (Expression 9)

Since the difference T_{1,N}−T_{1,N-1} of the required times is equal to the time deviation dT_{1,N} detected by the timing sensor, Expression 10 below is obtained.

dT_{1,N}=I_{N}−I₀

=(Td_{N}−Td_{N-1})−I₀

=T_{1,N}−T_{1,N-1} (Expression 10)

That is, the time deviation dT_{1,N} of the required times for the N−1th and Nth D1s to reach the timing sensor is obtained by subtracting the time difference (1/f₀=time interval I₀) at which the DLs are discharged from the time interval I_{N} of the N−1th and Nth DL passage times.

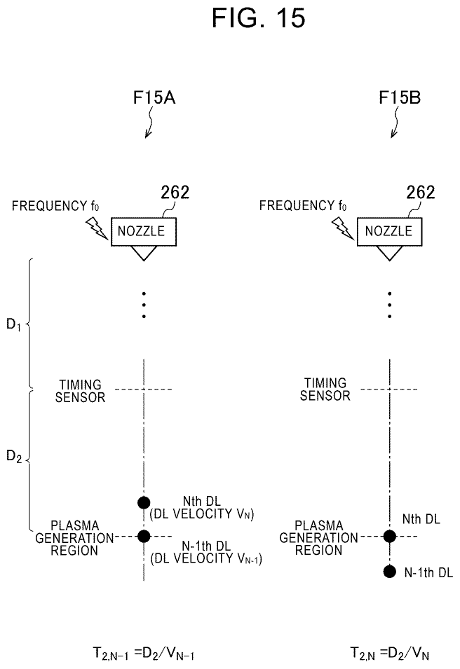

FIG. 15 shows the relationship among the distance D₁ from the nozzle 262 to the detection region of the timing sensor, a distance D₂ from the detection region of the timing sensor to the plasma generation region 25, and the N−1th and Nth droplets. F15A on the left of FIG. 15 shows the state of the N−1th droplet having reached the plasma generation region 25, and F15B on the right thereof shows the state of the Nth droplet having reached the plasma generation region 25.

The required times T_{2,N-1} and T_{2,N} for the N−1th and Nth droplets to move by the distance D₂ from the detection region of the timing sensor to the plasma generation region 25 are obtained by Expression 11 and Expression 12 below.

T_{2,N-1}=D₂/V_{N-1}=(D₂/D₁)×T_{1,N-1} (Expression 11)

T_{2,N}=D₂/V_{N}=(D₂/D₁)×T_{1,N} (Expression 12)

Here, Expression 8 is applied to Expression 11, while Expression 9 is applied to Expression 12.

The estimated time deviation dT_{2,N} for the plasma generation region 25 is expressed by following Expression 13 when the velocities V_{N-1}, V_{N} of the droplets are constant between the distance D₁ and the distance D₂.

dT_{2,N}=T_{2,N}−T_{2,N-1}={(D₂/D₁)×T_{1,N}}−{(D₂/D₁)×T_{1,N-1}}=(D₂/D₁)×dT_{1,N} (Expression 13)

Here, Expression 10 is applied to Expression 13.

That is, by multiplying the time deviation dT_{1,N} measured by the timing sensor by D₂/D₁, it is possible to estimate the estimated time deviation dT₂,N for the plasma generation region 25. The time deviation dT_{2,N}=T_{2,N}−T_{2,N-1} for the N−1th and Nth droplets required to reach the plasma generation region 25 corresponds to the difference in the delay time.

The Nth droplet is an example of the “first target” in the present disclosure, and the N−1th droplet is an example of the “second target” in the present disclosure. The distance D₁ is an example of the “first distance” in the present disclosure, and the distance D₂ is an example of the “second distance” in the present disclosure. Further, D₂/D₁ is an example of the “ratio of the second distance to the first distance” in the present disclosure. The required time T_{1,N} is an example of the “first required time” in the present disclosure, and the required time T_{1,N-1} is an example of the “second required time” in the present disclosure.

### 5.5 Operation

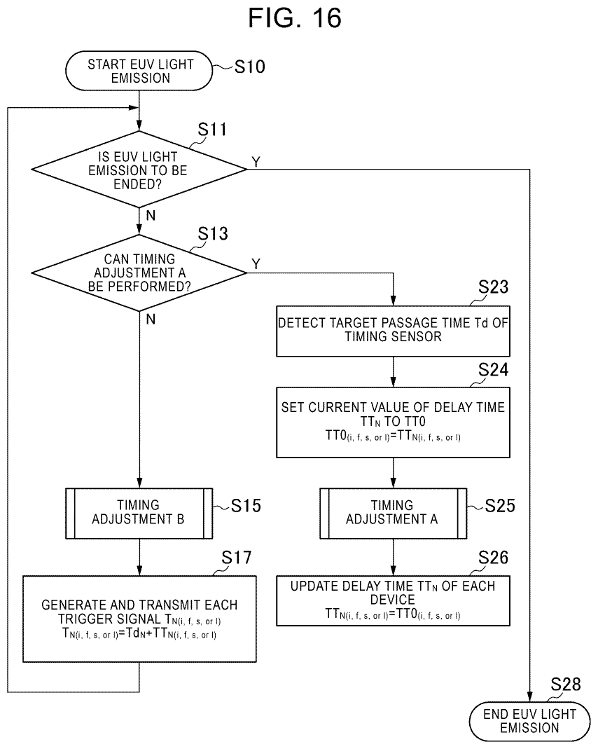

FIG. 16 is a flowchart showing an example of the operation of the EUV light generation apparatus 1A. The flowchart shown in FIG. 16 will be described in terms of differences from that shown in FIG. 7.

In the flowchart of FIG. 16, step S12 of FIG. 7 is deleted, and steps S15 and S17 are included instead of step S14. Further, in FIG. 16, steps S23 and S24 to be performed when the determination result of step S13 is YES is added, and step S26 to be performed after the timing adjustment A of step S25 is further added.

When the determination result of step S13 is YES, the processor 5A performs a flow of steps S23 to S26 including the process of the timing adjustment A (step S25) in parallel with step S15. The flow of steps S23 to S26 will be described later.

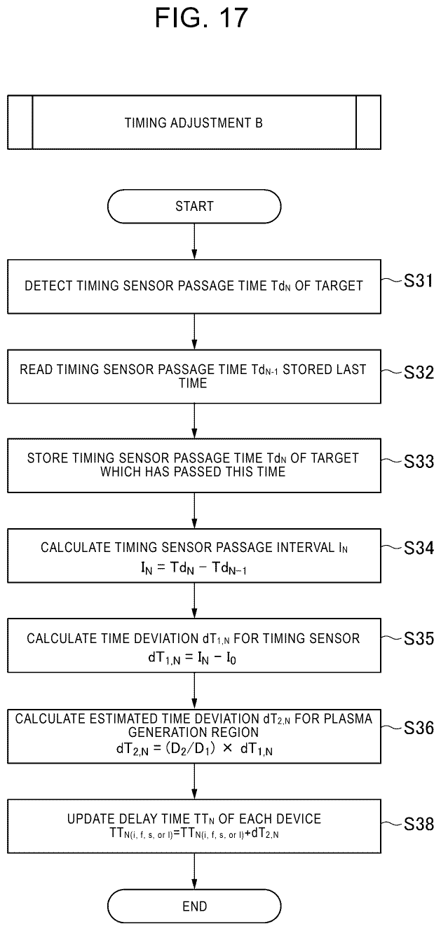

When the determination result of step S13 is NO, the processor 5A independently performs the process of the timing adjustment B of step S15. Details of the flow of the timing adjustment B will be described later with reference to FIG. 17.

After step S15, the processor 5A proceeds to step S17. In step S17, the trigger selection and delay device 53A generates and transmits the trigger signal TN_{(i, f, s, or 1)} to each device.

TN_{(i,f,s, or 1)}=Td_{N}+TT_{N(i,f,s, or 1)} (Expression 7)

Further, the trigger selection and delay device 53A notifies the arithmetic control processor 51A of completion of the transmission process of the trigger signal T_{N(i, f, s, or 1)} to each device. After step S17, processing returns to step S11. Other steps may be similar to those in the flowchart of FIG. 7.

FIG. 17 is a flowchart showing an example of the process of the timing adjustment B to be applied in step S15.

In step S31, the pulse waveform processing unit 55A detects the timing sensor passage time Td_{N} of the Nth target 27. That is, with respect to the output signal of the timing sensor at the timing of the droplet passage, the pulse waveform processing unit 55A detects, as the passage timing of the target 27, the midpoint ta=(t1+t2)/2 from the time t1 at which the output signal decreases to the threshold set to a constant ratio (e.g., 90%) and the time t2 at which the decreased signal is recovered to the threshold. Instead of obtaining from t1 and t2, the passage timing ta may be the time point (lower peak point) at which the detection signal is minimized. In the first embodiment, the timing sensor passage time Td_{N} is detected at the timing of ta=Td, and output to the trigger selection and delay device 53A.

In step S32, the trigger selection and delay device 53A performs reading of the timing sensor passage time Td_{N-1} previously stored last time. That is, the trigger selection and delay device 53A reads, in the process of the last time (N−1th target 27), the value of the parameter Td_{B} stored in step S33 described later as the time corresponding to the timing sensor passage time Td_{N-1} of the immediately previous target in the process of this time (Nth target 27).

In step S33, the trigger selection and delay device 53A stores, as the parameter Td_{B}, the timing sensor passage time Td_{N} of the target 27, obtained in step S31, which has passed this time. The stored Td_{B} is read as the time corresponding to the timing sensor passage time Td_{N-1} of the immediately previous droplet in step S32 of the next process.

In step S34, the trigger selection and delay device 53A calculates the time interval I_{N} from Td_{N} and Td_{N-1} by Expression 5.

I_{N}=Td_{N}−Td_{N-1} (Expression 5)

For example, when the current passing droplet is the first droplet at the beginning of the flow, the time of Td_{N-1} becomes indefinite, and I_{N} calculated from Expression 5 may be an abnormal value. Therefore, in a case in which I_{N} is equal to or more than two times the time interval I₀ for generating the targets 27, steps S35, S36, and S38 may be skipped.

In step S35, the trigger selection and delay device 53A receives the time interval I₀ for generating the targets 27 from the arithmetic control processor 51A and calculates the time deviation dT_{1,N} by Expression 6.

dT_{1,N}=I_{N}−I₀ (Expression 6)

In step S36, the trigger selection and delay device 53A calculates the estimated time deviation dT_{2,N} for the plasma generation region 25 by Expression 13.

dT_{2,N}=(D₂/D₁)×dT_{1,N} (Expression 13)

In step S38, the trigger selection and delay device 53A updates the delay time TT_{N(i, f, s, or 1)} by adding the estimated time deviation dT_{2,N} to the delay time TT_{N(i, f, s, or 1)} of the corresponding device (Expression 14).

TT_{N(i,f,s, or 1)}=TT_{N(i,f,s, or 1)}+dT_{2,N} (Expression 14)

The left side of Expression 14 represents the delay time after updating (after correction), and TT_{N(i, f, s, or 1)} on the right side represents the delay time before updating (before correction).

After the process of step S38, the flowchart of FIG. 17 is ended, and processing proceeds to step S17 of FIG. 16.

When the determination result of step S13 of FIG. 16 is YES, the processes of steps S23 to S26 are performed in parallel with the loop (steps S11 to S17) including steps S15 and S17 described above.

In step S23, the pulse waveform processing unit 55A detects the target passage time Td of the timing sensor and transmits it to the trigger selection and delay device 53A. Here, for ease of explanation, description will be provided on a case in which the timing adjustment A described below is performed based on the passage time Td of the Nth target 27 (first target) to be processed in the timing adjustment B, or a third target being different from the N−1th target 27 (second target).

However, since the timing adjustment A (step S25) and the timing adjustment B (step S15) are performed in parallel, the above includes a case in which the third target is the same as the first target or the second target.

In step S24, the arithmetic control processor 51A reads the value of the delay time TT_{N(i, f, s, or 1)} currently set in the trigger selection and delay device 53A and sets it as the initial value of TT0_{(i, f, s, or 1)} before the process of the timing adjustment A is started.

TT0_{(i,f,s, or 1)}=TT_{N(i,f,s, or 1)} (Expression 15)

In step S25, the arithmetic control processor 51A updates TT0_{(i, f, s, or 1)} based on the captured image of the droplets according to the flowchart of FIG. 8.

In step S26, the arithmetic control processor 51A updates, by Expression 16 below, the delay time TT_{N(i, f, s, or 1)} of the trigger selection and delay device 53A with TT0_{(i, f, s, or 1)} updated through the timing adjustment A, and ends steps S23 to S26 which is the parallel processing.

TT_{N(i,f,s, or 1)}=TT0_{(i,f,s, or 1)} (Expression 16)

### 5.6 Effect

According to the EUV light generation apparatus 1A, due to the timing adjustment B, the difference of the required time (estimated time deviation dT_{2,N}) for each droplet from the detection region of the timing sensor to the plasma generation region 25 is calculated, thereby enabling adjustment of the delay time TT_{N(i, f, s, or 1)} for each droplet.

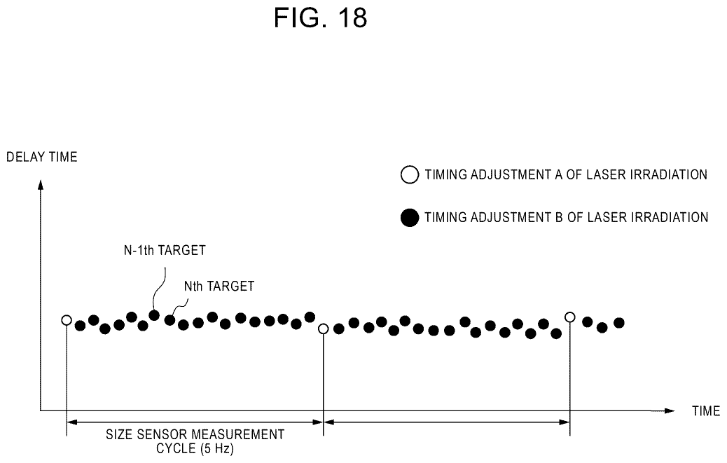

FIG. 18 is a graph showing an example of the delay time of the laser irradiation timing adjusted through the timing adjustment A and the timing adjustment B of the EUV light generation apparatus 1A. The horizontal axis represents time and the vertical axis represents the delay time TT_{N1}. White circles in FIG. 18 indicate delay times due to the timing adjustment A using the measurement values of the size sensor. Black circles in FIG. 18 indicate delay times due to the timing adjustment B using the DL passage time interval of the timing sensor. As shown in FIG. 18, the timing adjustment A is performed for the target 27 for each 5 Hz which is a size sensor measurement cycle, while the timing adjustment B can be performed for all the targets 27.

Accordingly, the EUV light generation apparatus 1A can perform laser irradiation timing correction continuously for the targets 27 to be used for EUV light emission. According to the EUV light generation apparatus 1A, the variation of the irradiation positions of the droplets in the vertical direction (Y direction) at the laser irradiation timing is reduced, and the energy stability of the EUV light is improved.

Further, according to the EUV light generation apparatus 1A, occurrence of fragments caused by the relative positional deviation between the target 27 and the pulse laser light 33 can be suppressed, and contamination of the EUV light concentrating mirror 23 can be suppressed.

### 5.7 Others

The process of the timing adjustment B in the first embodiment may be performed on all the droplets or may not be performed on some of the droplets. For example, the timing adjustment B may be performed for each droplet for EUV light emission (for each laser irradiation) shown in FIG. 5. In this case, when the droplet for EUV light emission is the Nth droplet, the correction of the delay time can be applied in the EUV light generation apparatus 1A if the timing sensor passage times Td_{N}, Td_{N-1} of the Nth and N−1th droplets are acquired (see FIG. 18).

Here, the distance D₁ and the distance D₂ may be determined based on design values of computer aided design (CAD) and the like.

### 6. Second Embodiment

### 6.1 Configuration

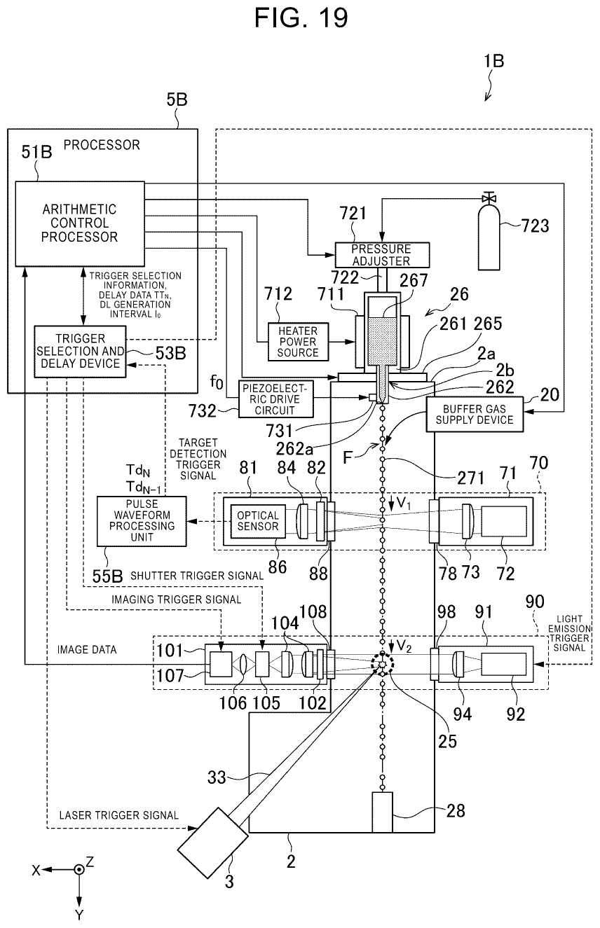

FIG. 19 shows an EUV light generation apparatus 1B according to a second embodiment. The configuration of the EUV light generation apparatus 1B will be described in terms of differences from the EUV light generation apparatus 1A shown in FIG. 11.

The EUV light generation apparatus 1B includes a buffer gas supply device 20 for supplying a buffer gas into the chamber 2. In the EUV light generation apparatus 1B, the buffer gas is flowed into the chamber 2 to protect the apparatus from tin particles and charged particles generated during plasma generation. When the buffer gas is a hydrogen gas, radicals or ions generated from the hydrogen gas react with the tin constituting the tin debris and a stannane (SnH₄) gas is generated. In this course, the tin adhered to surfaces of components is removed.

For example, the buffer gas supply device 20 is connected to the target supply path 2a, and may supply the buffer gas to the space between the nozzle 262 and the target passage detection device 70.

The EUV light generation apparatus 1B includes a pulse waveform processing unit 55B and a processor 5B instead of the pulse waveform processing unit 55A and the processor 5A of FIG. 11. The processor 5B includes an arithmetic control processor 51B and a trigger selection and delay device 53B. The buffer gas supply device 20 is controlled by the arithmetic control processor 51B. Other configurations are similar to those of the EUV light generation apparatus 1A.

### 6.2 Operation

Regarding the target 27 discharged from the nozzle 262, a velocity V₁ in the vicinity of the target passage detection device 70 and a velocity V₂ in the vicinity of the target image measurement device 90 (plasma generation region 25) are different due to the effect of the buffer gas supplied from the buffer gas supply device 20.

Therefore, the trigger selection and delay device 53B estimates the delay time deviation amount of the trigger signal in consideration with an effect coefficient k1 due to the buffer gas injected into the chamber 2. Effects of the buffer gas are, for example, acceleration and deceleration of the droplet by the injected buffer gas, and air resistance. Specifically, the relationship among the velocity V₁, the velocity V₂, and the effect coefficient k1 of the buffer gas is set as expressed in Expression 17.

V₁=k1×V₂ (Expression 17)

Along with this, the relational expression in the timing adjustment B is changed as follows.

T_{1,N}=D₁/V1_{N} (Expression 18)

T_{2,N}=D₂/V2_{N}=k1×(D₂/D₁)×T_{1,N} (Expression 19)

dT_{2,N}=k1×(D₂/D₁)×dT_{1,N} (Expression 20)

Here, V1_{N} in Expression 18 represents the velocity of the Nth droplet in the vicinity of the target passage detection device 70, and V2_{N} represents the velocity of the Nth droplet in the vicinity of the target image measurement device 90 (plasma generation region 25).

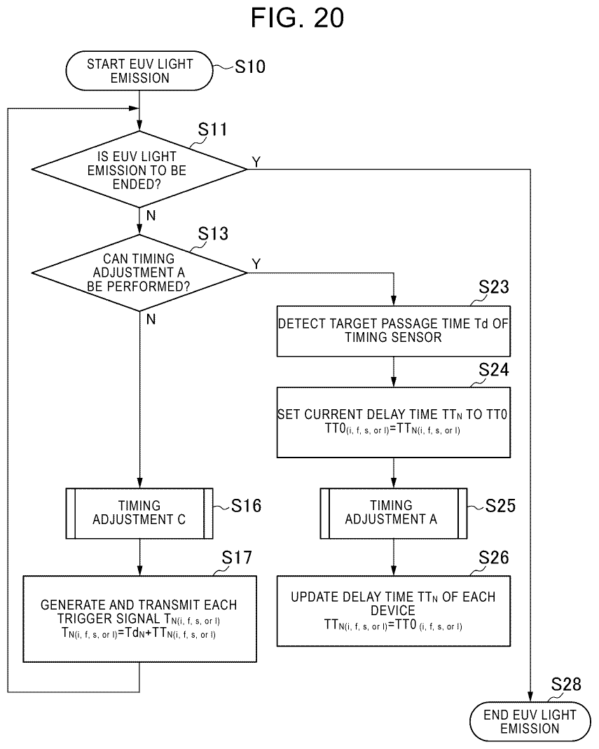

FIG. 20 is a flowchart showing an example of the operation of the EUV light generation apparatus 1B. The flowchart shown in FIG. 20 will be described in terms of differences from that shown in FIG. 16.

The flowchart shown in FIG. 20 includes timing adjustment C of step S16 instead of the timing adjustment B (step 15) of FIG. 16.

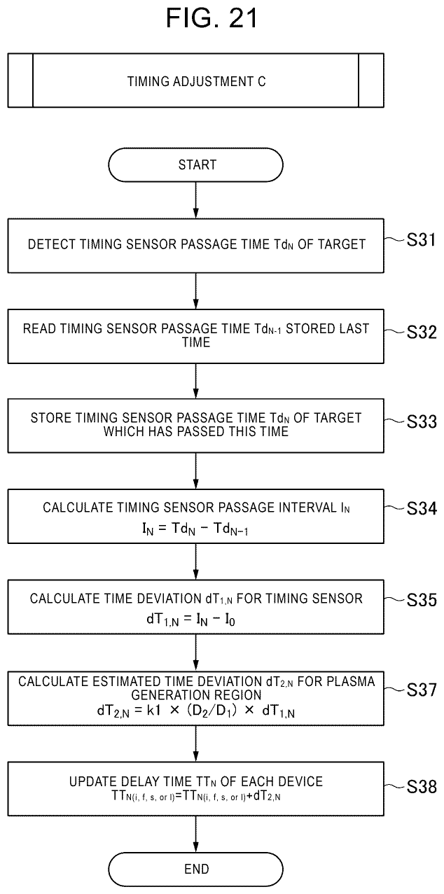

FIG. 21 is a flowchart showing an example of a subroutine of the process of the timing adjustment C to be applied in step S16. The flowchart shown in FIG. 21 will be described in terms of differences from that shown in FIG. 17. The flowchart shown in FIG. 21 includes step S37 instead of step S35 of FIG. 17.

In step S37, the arithmetic control processor 51B calculates the estimated time deviation dT_{2,N} for the plasma generation region 25 from Expression 20.

The effect coefficient k1 can be about 1. The value of the effect coefficient k1 may be obtained through simulation calculation, or experimentally specified. For example, the effect coefficient k1 is 1.00002 through simulation calculation under conditions of the assumed buffer gas. Other steps may be similar to those in the flowchart shown in FIG. 17.

### 6.3 Effect

According to the EUV light generation apparatus 1B, the delay time including the droplet velocity change due to the influence of the buffer gas can be corrected.

### 7. Third Embodiment

### 7.1 Configuration

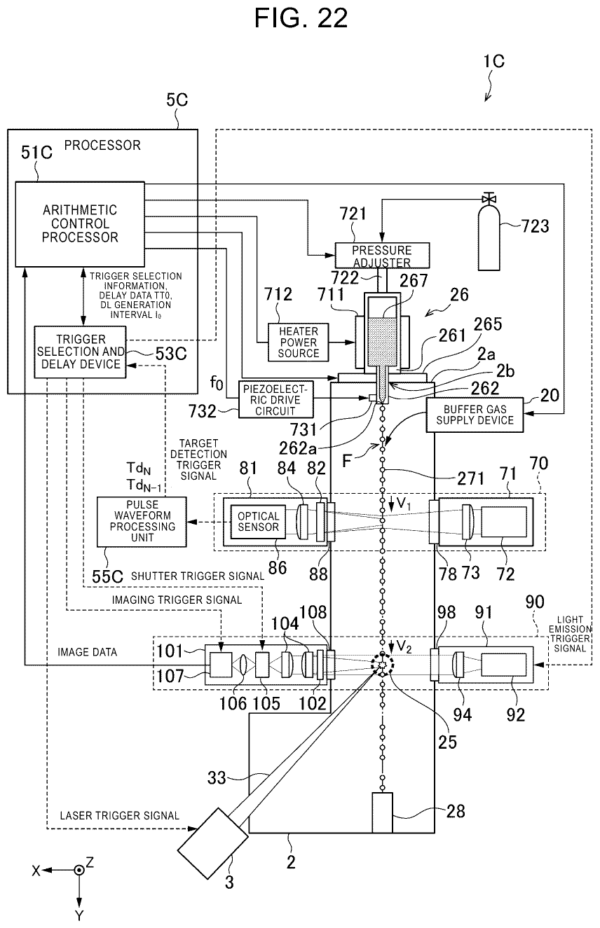

FIG. 22 shows the configuration of an EUV light generation apparatus 1C according to a third embodiment. The configuration of the EUV light generation apparatus 1C will be described in terms of differences from the EUV light generation apparatus 1B.

The EUV light generation apparatus 1C includes a pulse waveform processing unit 55C and a processor 5C instead of the pulse waveform processing unit 55B and the processor 5B of FIG. 19. The processor 5C includes an arithmetic control processor 51C and a trigger selection and delay device 53C.

In the EUV light generation apparatus 1C, the information of the delay time interchanged between the arithmetic control processor 51C and the trigger selection and delay device 53C differs from the information of the delay time interchanged between the arithmetic control processor 51B and the trigger selection and delay device 53B of the EUV light generation apparatus 1B.

That is, the trigger selection and delay device 53C generates the trigger signal T_{N} by adding the delay time TT0 and the estimated time deviation dT₂,N obtained by the size sensor (timing adjustment A) to the timing sensor passage time Td_{N} of the Nth droplet, and transmits it to each device. The delay time TT0 is an example of the “second delay time” in the present disclosure.

T_{N}=Td_{N}+TT0+dT_{2,N} (Expression 21)

Further, the arithmetic control processor 51C updates TT0 periodically through the timing adjustment A. Other configurations may be similar to those of the EUV light generation apparatus 1B.

### 7.2 Operation

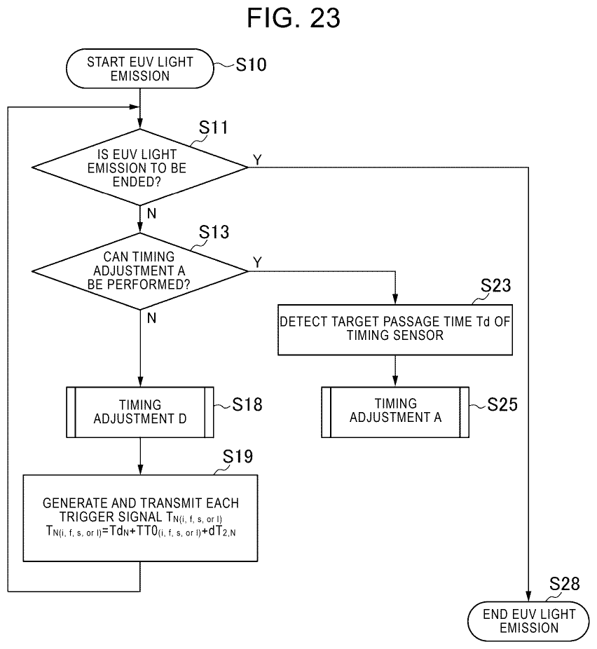

FIG. 23 is a flowchart showing an example of the operation of the EUV light generation apparatus 1C. The flowchart shown in FIG. 23 will be described in terms of differences from that shown in FIG. 20.

The flowchart shown in FIG. 23 includes timing adjustment D of step S18 instead of the timing adjustment C (step S16) in FIG. 20 and includes step S19 instead of step S17. Further, in the flowchart of FIG. 23, steps S24 and S26 of FIG. 20 are deleted, and when the determination result of step S13 is YES, the flow proceeding to steps S23 and S25 and the flow proceeding to step S18 and looping from step S11 to step S19 are performed in parallel.

When the determination result of step S13 is NO, processing proceeds to step S18.

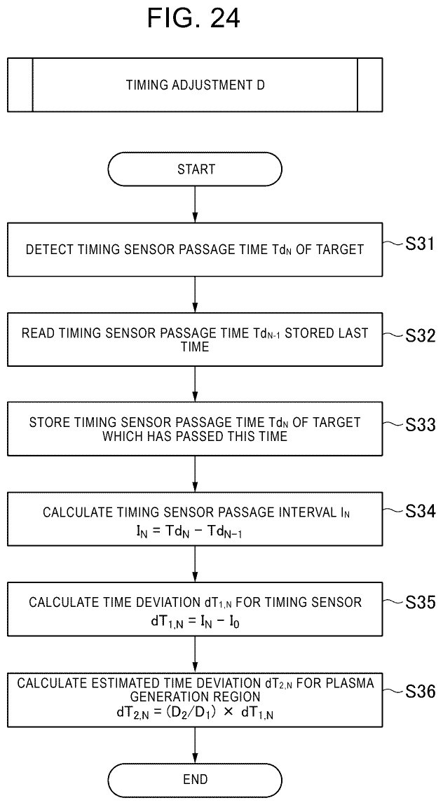

In step S18, the trigger selection and delay device 53C performs the timing adjustment D. The contents of the timing adjustment D will be described later with reference to FIG. 24.

In step S19 after step S18, the trigger selection and delay device 53C reads the delay time TT0 obtained through the timing adjustment A (step S25) from the arithmetic control processor 51C, and generates the timing of the trigger signal T_{N}(i, f, s, or 1) by adding the estimated time deviation dT₂,N obtained through the timing adjustment D (Expression 21) to transmit the trigger signal to each device.

After step S19, processing returns to step S11. Other steps may be similar to those in the flowchart of FIG. 20.

FIG. 24 is a flowchart showing an example of a subroutine of the process of the timing adjustment D to be applied in step S18.

The flowchart shown in FIG. 24 will be described in terms of differences from that shown in FIG. 17. In the flowchart of FIG. 24, step S38 of FIG. 17 is deleted, and the flowchart of FIG. 24 is ended by the completion of step S36. Other steps are similar to those in FIG. 17.

### 7.3 Effect

According to the third embodiment, the same effects can be obtained as the first embodiment.

### 8. Electronic Device Manufacturing Method

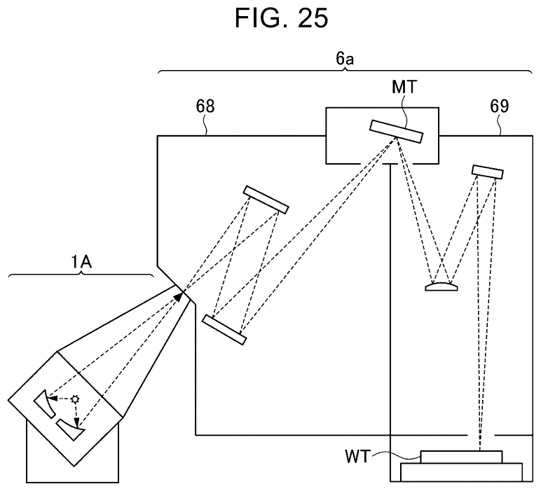

FIG. 25 schematically shows the configuration of an exposure apparatus 6a connected to the EUV light generation apparatus 1A. In FIG. 25, the exposure apparatus 6a as the external apparatus includes a mask irradiation unit 68 and a workpiece irradiation unit 69. The mask irradiation unit 68 illuminates, via a reflection optical system, a mask pattern of the mask table MT with the EUV light incident from the EUV light generation apparatus 1A. The workpiece irradiation unit 69 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

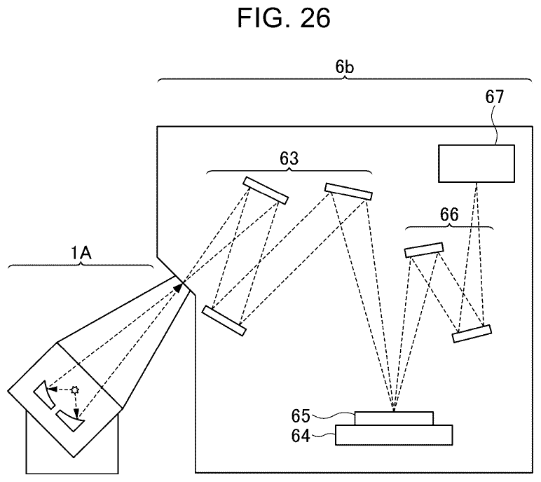

FIG. 26 schematically shows the configuration of an inspection apparatus 6b connected to the EUV light generation apparatus 1A. In FIG. 26, the inspection apparatus 6b as the external apparatus includes an illumination optical system 63 and a detection optical system 66. The illumination optical system 63 reflects the EUV light incident from the EUV light generation apparatus 1A to illuminate a mask 65 placed on a mask stage 64. Here, the mask 65 conceptually includes a mask blanks before a pattern is formed. The detection optical system 66 reflects the EUV light from the illuminated mask 65 and forms an image on a light receiving surface of a detector 67. The detector 67 having received the EUV light obtains an image of the mask 65. The detector 67 is, for example, a time delay integration (TDI) camera. Inspection for a defect of the mask 65 is performed based on the image of the mask 65 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

Instead of the EUV light generation apparatus 1A in FIGS. 25 and 26, the EUV light generation apparatus 1B or 1C can be used.

### 9. Processor

The processor such as the processors 5, 5A, 5B, 5C and the arithmetic control processors 51, 51A, 51A, 51C may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a central processing unit (CPU) or a special-purpose processing device such as a graphics processing unit (GPU).

Alternatively, the processor may be programmed as software to execute the various processes included in the present disclosure. For example, the processor may be implemented in a dedicated device such as an application specific integrated circuit (ASIC) or a programmable device such as a field programmable gate array (FPGA).

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

The arithmetic control processors 51A, 51B, 51C, the trigger selection and delay devices 53A, 53B, 53C, and the pulse waveform processing units 55A, 55B, 55C shown in FIGS. 11, 19, and 22 may perform, in order to perform the processing described in the embodiments, arithmetic processing using a processor and a memory after performing digitization using an analog electric signal processing circuit or an AD converter.

Further, processing may be performed by dividing into a plurality of processing devices with respect to dividing of processing functions different from the above, or may be performed by aggregating into one processing device. For example, the arithmetic control processor 51A and the trigger selection and delay device 53A may perform processing as being aggregated into one processing device. Such selections are appropriately performed in accordance with the speed and accuracy of the processing.

### 10. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. An extreme ultraviolet light generation system configured to generate extreme ultraviolet light by irradiating targets with pulse laser light, comprising:
a chamber;
a target supply unit configured to continuously generate the targets at a specific time interval and supply the targets into the chamber;
a timing sensor configured to detect the target passing through a first region and output a signal;
a laser device configured to radiate the pulse laser light toward the target having passed through the first region; and
a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

2. The extreme ultraviolet light generation system according to claim 1,
wherein the timing sensor includes a light source configured to illuminate the first region with light and a sensor configured to receive the light.

3. The extreme ultraviolet light generation system according to claim 1,
wherein the target supply unit includes a piezoelectric element for generating the targets, and
the time interval is an inverse of a vibration frequency of the piezoelectric element.

4. The extreme ultraviolet light generation system according to claim 1,
wherein the processor determines the timing based on the first time and a time deviation, with respect to the time interval, of a passage interval being a time difference between the first time and the second time.

5. The extreme ultraviolet light generation system according to claim 4,
wherein the processor obtains an estimated time deviation, from the time deviation, indicating a time difference between a first required time for the first target to reach a plasma generation region from the first region and a second required time for the second target to reach the plasma generation region from the first region, and determines the timing based on the first time and the estimated time deviation.

6. The extreme ultraviolet light generation system according to claim 5,
wherein the processor obtains the estimated time deviation by multiplying the time deviation by a ratio of a second distance from the first region to the plasma generation region to a first distance from a nozzle of the target supply unit outputting the targets to the first region.

7. The extreme ultraviolet light generation system according to claim 5,
further comprising a buffer gas supply device configured to inject a buffer gas into the chamber,
wherein the processor calculates the estimated time deviation based on the time deviation and an influence coefficient due to the buffer gas.

8. The extreme ultraviolet light generation system according to claim 5,
wherein the processor updates a first delay time by adding the estimated time deviation to the first delay time, and determines the timing by adding the updated first delay time to the first time.

9. The extreme ultraviolet light generation system according to claim 8,
further comprising an image sensor configured to image a second region including the plasma generation region,
wherein the processor updates the first delay time based on a difference between a position of a third target acquired by the image sensor and a reference target position.

10. The extreme ultraviolet light generation system according to claim 9,
wherein the reference target position is set in the plasma generation region.

11. The extreme ultraviolet light generation system according to claim 9, further comprising:
a flash lamp configured to illuminate the target in the second region to be imaged by the image sensor; and
a shutter configured to regulate an exposure time for the image sensor,
wherein the processor determines at least one of an imaging timing of the image sensor, a light emission timing of the flash lamp, and an operation timing of the shutter based on the first time and the estimation time deviation.

12. The extreme ultraviolet light generation system according to claim 5,
wherein the processor determines the timing by adding a second delay time and the estimated time deviation to the first time.

13. The extreme ultraviolet light generation system according to claim 12,
further comprising an image sensor configured to image a second region including the plasma generation region,
wherein the processor updates the second delay time based on a difference between a position of a third target acquired by the image sensor and a reference target position.

14. The extreme ultraviolet light generation system according to claim 13,
wherein the reference target position is set in the plasma generation region.

15. The extreme ultraviolet light generation system according to claim 13, further comprising:
a flash lamp configured to illuminate the target in the second region to be imaged by the image sensor; and
a shutter configured to regulate an exposure time for the image sensor,
wherein the processor determines at least one of an imaging timing of the image sensor, a light emission timing of the flash lamp, and an operation timing of the shutter based on the first time and the estimation time deviation.

16. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system being configured to generate the extreme ultraviolet light by irradiating targets with pulse laser light, and comprising:
a chamber;
a target supply unit configured to continuously generate the targets at a specific time interval and supply the targets into the chamber;
a timing sensor configured to detect the target passing through a first region and output a signal;
a laser device configured to radiate the pulse laser light toward the target having passed through the first region; and
a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.

17. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
the extreme ultraviolet light generation system being configured to generate the extreme ultraviolet light by irradiating targets with pulse laser light, and comprising:
a chamber;
a target supply unit configured to continuously generate the targets at a specific time interval and supply the targets into the chamber;
a timing sensor configured to detect the target passing through a first region and output a signal;
a laser device configured to radiate the pulse laser light toward the target having passed through the first region; and
a processor configured to obtain first time when a first target has passed through the first region from the signal and second time when a second target generated immediately before the first target has passed through the first region, and determine a timing at which the first target is irradiated with the pulse laser light of the laser device based on the first time, the second time, and the time interval.
